(19) United States
(12) Patent Application Publication
(10) Pub. No.: US 2012/0152295 A1
(43) Pub. Date: Jun. 21, 2012

(54) ARRAYS OF FILLED NANOSTRUCTURES WITH PROTRUDING SEGMENTS AND METHODS THEREOF

(75) Inventors: Gabriel A. Matus, San Francisco, CA (US); Mingqiang Yi, San Pablo, CA (US); Matthew L. Scullin, San Francisco, CA (US); Justin Tynes Kardel, Oakland, CA (US)

(73) Assignee: Alphabet Energy, Inc., Hayward, CA (US)

(21) Appl. No.: 13/331,768

(22) Filed: Dec. 20, 2011

Related U.S. Application Data
(60) Provisional application No. 61/425,362, filed on Dec. 21, 2010.

(51) Int. Cl. H01L 35/02; H01L 33/48; H01L 35/34; B82Y 99/00; B82Y 40/00

(52) U.S. Cl. 136/200; 438/54; 136/201; 977/840; 977/948; 257/E21.506

(57) ABSTRACT

A structure and method for at least one array of nanowires partially embedded in a matrix includes nanowires and one or more fill materials located between the nanowires. Each of the nanowires including a first segment associated with a first end, a second segment associated with a second end, and a third segment between the first segment and the second segment. The nanowires are substantially parallel to each other and are fixed in position relative to each other by the one or more fill materials. The third segment is substantially surrounded by the one or more fill materials. The first segment protrudes from the one or more fill materials.

### CROSS-REFERENCES TO RELATED APPLICATIONS

This application claims priority to U.S. Provisional Application No. 61/425,362, filed Dec. 21, 2010, commonly assigned and incorporated by reference herein for all purposes.

Additionally, this application is related to U.S. patent application Ser. Nos. 13/299,179 and 13/308,945, which are incorporated by reference herein for all purposes.

### STATEMENT AS TO RIGHTS TO INVENTIONS MADE UNDER FEDERALLY SPONSORED RESEARCH OR DEVELOPMENT

Work described herein has been supported, in part, by U.S. Air Force SBIR Contract No. FA8650-10-M-2031 and U.S. Army SBIR Contract No. W911Qy-10-C-0063. The United States Government may therefore have certain rights in the invention.

### BACKGROUND OF THE INVENTION

The present invention is directed to nanostructures. More particularly, the invention provides arrays of filled nanostructures with partially protruding segments and methods thereof. Merely by way of example, the invention has been applied to arrays of nanostructures embedded in one or more fill materials and having protruding segments and contacts for use in thermoelectric devices. However, it would be recognized that the invention has a much broader range of applicability, including but not limited to use in solar power, battery electrodes and/or energy storage, catalysis, and/or light emitting diodes.

Thermoelectric materials are ones that, in the solid state and with no moving parts, can, for example, convert an appreciable amount of thermal energy into electricity in an applied temperature gradient (e.g., the Seebeck effect) or pμmp heat in an applied electric field (e.g., the Peltier effect). The applications for solid-state heat engines are nμmerous, including the generation of electricity from various heat sources whether primary or waste, as well as the cooling of spaces or objects such as microchips and sensors. Interest in the use of thermoelectric devices that comprise thermoelectric materials has grown in recent years in part due to advances in nano-structured materials with enhanced thermoelectric performance (e.g., efficiency, power density, or “thermoelectric figure of merit” ZT, where ZT is equal to S²σ/k and S is the Seebeck coefficient, σ the electrical conductivity, and k the thermal conductivity of the thermoelectric material) and also due to the heightened need both for systems that either recover waste heat as electricity to improve energy efficiency or cool integrated circuits to improve their performance.

To date, thermoelectrics have had limited commercial applicability due to the poor cost performance of these devices compared to other technologies that accomplish similar means of energy generation or refrigeration. Where other technologies usually are not as suitable as thermoelectrics for use in lightweight and low footprint applications, thermoelectrics often have nonetheless been limited by their prohibitively high costs. Important in realizing the usefulness of thermoelectrics in commercial applications is the manufacturability of devices that comprise high-performance thermoelectric materials (e.g., modules). These modules are preferably produced in such a way that ensures, for example, maximμm performance at minimμm cost.

The thermoelectric materials in presently available commercial thermoelectric modules are generally comprised of bismuth telluride or lead telluride, which are both toxic, difficult to manufacture with, and expensive to procure and process. With a strong present need for both alternative energy production and microscale cooling capabilities, the driving force for highly manufacturable, low cost, high performance thermoelectrics is growing.

Thermoelectric devices are often divided into thermoelectric legs made by conventional thermoelectric materials such as Bi₂Te₃ and PbTe, contacted electrically, and assembled in a refrigeration (e.g., Peltier) or energy conversion (e.g., Seebeck) device. This often involves bonding the thermoelectric legs to metal contacts in a configuration that allows a series-configured electrical connection while providing a thermally parallel configuration, so as to establish a temperature gradient across all the legs simultaneously. However, many drawbacks may exist in the production of conventional thermoelectric devices. For example, costs associated with processing and assembling the thermoelectric legs made externally is often high. The conventional processing or assembling method usually makes it difficult to manufacture compact thermoelectric devices needed for many thermoelectric applications. Conventional thermoelectric materials are usually toxic and expensive.

Nanostructures often refer to structures that have at least one structural dimension measured on the nanoscale (e.g., between 0.1 nm and 1000 nm). For example, a nanowire is characterized as having a cross-sectional area that has a distance across that is measured on the nanoscale, even though the nanowire may be considerably longer in length. In another example, a nanotube, or hollow nanowire, is characterized by having a wall thickness and total cross-sectional area that has a distance across that is measured on the nanoscale, even though the nanotube may be considerably longer in length. In yet another example, a nanohole is characterized as a void having a cross-sectional area that has a distance across that is measured on the nanoscale, even though the nanohole may be considerably longer in depth. In yet another example, a nanomesh is an array, sometimes interlinked, including a plurality of other nanostructures such as nanowires, nanotubes, and/or nanoholes.

Nanostructures have shown promise for improving thermoelectric performance. The creation of 0D, 1D, or 2D nanostructures from a thermoelectric material may improve the thermoelectric power generation or cooling efficiency of that material in some instances, and sometimes very significantly (a factor of 100 or greater) in other instances. However, many limitations exist in terms of alignment, scale, and mechanical strength for the nanostructures needed in an actual macroscopic thermoelectric device comprising many nanostructures. Processing such nanostructures using methods that are similar to the processing of silicon would have tremendous cost advantages. For example, creating nanostructure arrays with planar surfaces supports planar semiconductor processes like metalization.

Hence, it is highly desirable to form these arrays of nanostructures from materials with advantageous electrical, thermal, and mechanical properties for use in thermoelectric devices.

### BRIEF SUMMARY OF THE INVENTION

The present invention is directed to nanostructures. More particularly, the invention provides arrays of filled nanostructures with partially protruding segments and methods thereof. Merely by way of example, the invention has been applied to arrays of nanostructures embedded in one or more fill materials and having protruding segments and contacts for use in thermoelectric devices. However, it would be recognized that the invention has a much broader range of applicability, including but not limited to use in solar power, battery electrodes and/or energy storage, catalysis, and/or light emitting diodes.

According to one embodiment, a structure for at least one array of nanowires partially embedded in a matrix includes nanowires and one or more fill materials located between the nanowires. Each of the nanowires including a first segment associated with a first end, a second segment associated with a second end, and a third segment between the first segment and the second segment. The nanowires are substantially parallel to each other and are fixed in position relative to each other by the one or more fill materials. The third segment is substantially surrounded by the one or more fill materials. The first segment protrudes from the one or more fill materials.

According to another embodiment, a structure for at least one array of nanostructures partially embedded in a matrix includes nanostructures and one or more fill materials. Each of the nanostructures including a first segment associated with a first end, a second segment associated with a second end, and a third segment between the first segment and the second segment, the nanostructures corresponding to voids. The one or more fill materials are located at least within the voids. Each of the nanostructures includes a semiconductor material. The nanostructures are substantially parallel to each other and are fixed in position relative to each other by the one or more fill materials. The voids corresponding to the third segment are substantially filled by the one or more fill materials. The first segment protrudes from the one or more fill materials.

According to yet another embodiment, a thermoelectric device, the device includes nanostructures, each of the nanostructures including a first segment associated with a first end, a second segment associated with a second end, and a third segment between the first segment and the second segment, the nanostructures corresponding to voids; one or more fill materials located at least within the voids; one or more first electrodes associated with the first segment; and one or more second electrodes associated with the second segment. Each of the nanostructures includes a semiconductor material. The nanostructures are substantially parallel to each other and are fixed in position relative to each other by the one or more fill materials. The voids corresponding to the third segment are substantially filled by the one or more fill materials. The first segment protrudes from the one or more fill materials. The second segment protrudes from the one or more fill materials.

According to yet another embodiment, a method for making a thermoelectric device includes forming nanostructures in a substrate, the nanostructures including a semiconductor material, a first segment associated with a first end, a second segment associated with a second end, and a third segment between the first segment and the second segment; filling voids corresponding to the nanostructures with at least one or more fill materials; exposing at least the first segment; forming one or more first electrodes associated with the first segment; removing at least a portion of the substrate; exposing at least the second segment; and forming one or more second electrodes associated with the second segment. The process for filling the voids includes keeping the nanostructures substantially parallel to each other, fixing the nanostructures in position relative to each other by the one or more fill materials, and substantially filling the voids corresponding to the third segment with the one or more fill materials.

Depending upon the embodiment, one or more of these benefits may be achieved. These benefits and various additional objects, features, and advantages of the present invention can be fully appreciated with reference to the detailed description and accompanying drawings that follow.

### BRIEF DESCRIPTION OF THE DRAWINGS

FIG. 1 is a simplified diagram showing a filled array of nanowires with protruding segments according to one embodiment of the present invention.

FIG. 2 is a simplified diagram showing a filled array of nanowires with protruding segments and contacts according to one embodiment of the present invention.

FIG. 3 is a simplified diagram showing a filled array of nanowires with protruding segments and contacts according to another embodiment of the present invention.

FIG. 4 is a simplified diagram showing a filled array of nanowires with protruding segments and contacts according to another embodiment of the present invention.

FIG. 5 is a simplified diagram showing an array of nanostructures with contacts and electrodes according to one embodiment of the present invention.

FIG. 6 is a simplified diagram showing a method for forming a filled array of nanostructures with protruding segments, contacts, and electrodes according to one embodiment of the present invention.

FIG. 7 is a simplified diagram showing the process for forming an array of nanostructures in a substrate as part of the method for forming an array of nanostructures with protruding segments, contacts, and electrodes according to one embodiment of the present invention.

FIG. 8A is a simplified diagram showing a substrate used for the process 310 for providing a substrate as part of the method 3600 for forming an array of nanostructures with protruding segments, contacts, and electrodes according to one embodiment of the present invention.

FIG. 8B is a simplified diagram showing an array of nanostructures in a substrate as formed by the process as shown in FIG. 7 as part of the method for forming an array of nanostructures with protruding segments, contacts, and electrodes according to one embodiment of the present invention.

FIG. 9 is a simplified diagram showing the process for filling the array of nanostructures in a substrate as part of the method for forming an array of nanostructures with protruding segments, contacts, and electrodes according to one embodiment of the present invention.

FIG. 10A is a simplified diagram of a filled array of nanostructures in a substrate as formed by the process of FIG. 9 as part of the method for forming an array of nanostructures with protruding segments, contacts, and electrodes according to one embodiment of the present invention.

FIG. 10B is a simplified diagram of a filled and planarized array of nanostructures in a substrate as formed by the planarization process as part of the method for forming an array of nanostructures with protruding segments, contacts, and electrodes according to one embodiment of the present invention.

FIG. 10C is a simplified diagram of a filled and planarized array of nanostructures with exposed segments as formed by the process for exposing nanostructure segments as part of the method for forming an array of nanostructures with protruding segments, contacts, and electrodes according to one embodiment of the present invention.

FIG. 10D is a simplified diagram of the array of nanostructures with one or more contacts on the exposed segments of the nanostructures as formed by the process for forming one or more contacts as part of the method for forming an array of nanostructures with protruding segments, contacts, and electrodes according to one embodiment of the present invention.

FIG. 10E is a simplified diagram of the array of nanostructures with one or more electrodes on the one or more contacts as formed by the process for metalization as part of the method for forming an array of nanostructures with protruding segments, contacts, and electrodes according to one embodiment of the present invention.

FIG. 11A is a simplified diagram showing a filled array of nanostructures in a substrate as formed as part of the process of FIG. 9 as part of the method for forming an array of nanostructures with protruding segments, contacts, and electrodes according to another embodiment of the present invention.

FIG. 11B is a simplified diagram of a filled and planarized array of nanostructures with exposed segments as formed by the process for exposing the nanostructure segments as part of the method for forming an array of nanostructures with protruding segments, contacts, and electrodes according to another embodiment of the present invention.

FIG. 11C is a simplified diagram of the array of nanostructures with one or more contacts on the exposed segments of the nanostructures as formed by the process for forming one or more contacts as part of the method for forming an array of nanostructures with protruding segments, contacts, and electrodes according to one embodiment of the present invention.

FIG. 11D is a simplified diagram of the array of nanostructures with one or more electrodes on the one or more contacts as formed by the metalization process as part of the method for forming an array of nanostructures with protruding segments, contacts, and electrodes according to one embodiment of the present invention.

FIG. 12A is a simplified diagram of the array of nanostructures with one or more electrodes affixed to an additional substrate as formed by the process for affixing an additional substrate as part of the method for forming an array of nanostructures with protruding segments, contacts, and electrodes according to one embodiment of the present invention.

FIG. 12B is a simplified diagram of the array of nanostructures with the substrate removed as formed by the process for removing material as part of the method for forming an array of nanostructures with protruding segments, contacts, and electrodes according to one embodiment of the present invention.

FIG. 12C is a simplified diagram of the array of nanostructures with one or more contacts on the exposed segments of the array nanostructures as formed by the process for forming one or more contacts as part of the method for forming an array of nanostructures with protruding segments, contacts, and electrodes according to one embodiment of the present invention.

FIG. 12D is a simplified diagram of the array of nanostructures with one or more electrodes on the one or more contacts as formed by the metalization process as part of the method for forming an array of nanostructures with protruding segments, contacts, and electrodes according to one embodiment of the present invention.

FIG. 13A is a simplified diagram of an array of nanostructures affixed to an additional substrate mounted in a lapping jig before the process for removing material as part of the method for forming an array of nanostructures with protruding segments, contacts, and electrodes according to one embodiment of the present invention.

FIG. 13B is a simplified diagram of an array of nanostructures affixed to an additional substrate mounted in a lapping jig after the process for exposing the exposed segments of the nanostructure as part of the method for forming an array of nanostructures with protruding segments, contacts, and electrodes according to one embodiment of the present invention.

FIG. 14 is a scanning electron microscope image showing a surface of an array of nanostructures before exposure of the exposed segments of the array of nanostructures as part of the method for forming an array of nanostructures with protruding segments, contacts, and electrodes according to one embodiment of the present invention.

FIG. 15 is a scanning electron microscope image showing a surface of an array of nanostructures after exposure of the exposed segments of the array of nanostructures as part of the method for forming an array of nanostructures with protruding segments, contacts, and electrodes according to one embodiment of the present invention.

### DETAILED DESCRIPTION OF THE INVENTION

The present invention is directed to nanostructures. More particularly, the invention provides arrays of filled nanostructures with partially protruding segments and methods thereof. Merely by way of example, the invention has been applied to arrays of nanostructures embedded in one or more fill materials and having protruding segments and contacts for use in thermoelectric devices. However, it would be recognized that the invention has a much broader range of applicability, including but not limited to use in solar power, battery electrodes and/or energy storage, catalysis, and/or light emitting diodes.

In general, the usefulness of a thermoelectric material depends upon the physical geometry of the material. For example, the larger the surface area of the thermoelectric material that is presented on the hot and cold sides of a thermoelectric device, the greater the ability of the thermoelectric device to support heat and/or energy transfer through an increase in power density. In another example, a suitable minimμm distance (i.e., the length of the thermoelectric nanostructure) between the hot and cold sides of the thermoelectric material help to better support a higher thermal gradient across the thermoelectric device. This in turn may increase the ability to support heat and/or energy transfer by increasing power density.

One type of thermoelectric nanostructure is an array of nanowires with suitable thermoelectric properties. Nanowires can have advantageous thermoelectric properties, but to date, conventional nanowires and nanowire arrays have been limited in their technological applicability due to the relatively small sizes of arrays and the short lengths of fabricated nanowires. Another type of nanostructure with thermoelectric applicability is nanoholes or nanomeshes. Nanohole or nanomesh arrays also have limited applicability due to the small volμmes into which these nanostructures can be created or synthesized. For example, conventional nanostructures with lengths shorter than 100 μm have limited applicability in power generation and/or heat pμmping, and conventional nanostructures with lengths shorter than 10 μm have even less applicability because the ability to maintain or establish a temperature gradient using available heat exchange technology across these short lengths is greatly diminished. Furthermore, in another example, arrays smaller than the wafer dimensions of 4, 6, 8, and 12 inches are commercially limited.

The development of large arrays of very long nanostructures formed using semiconductor materials, such as silicon, can be useful in the formation of thermoelectric devices. For example, silicon nanostructures that have a low thermal conductivity, and formed within a predetermined area of a semiconductor substrate can be utilized to form a plurality of thermoelectric elements for making a uniwafer thermoelectric device. In another example, silicon nanowires formed within the predetermined area of the semiconductor substrate can be utilized as the n- or p-type legs or both in an assembled thermoelectric device.

However, there are often many difficulties in forming and utilizing arrays of nanostructures. For example, the nanostructures are often fragile and can be easily bent or broken. In another example, the nanostructures cannot be directly applied to high temperature surfaces. In yet another example, the nanostructures cannot be protruding to harsh environments. In yet another example, the nanostructures need a support material to form reliable planar metallic contacts required for thermoelectric applications. Consequently, arrays of nanostructures would benefit from being at least partially embedded in suitable fill materials that allow for the formation of electrodes at one or both ends of the nanostructures.

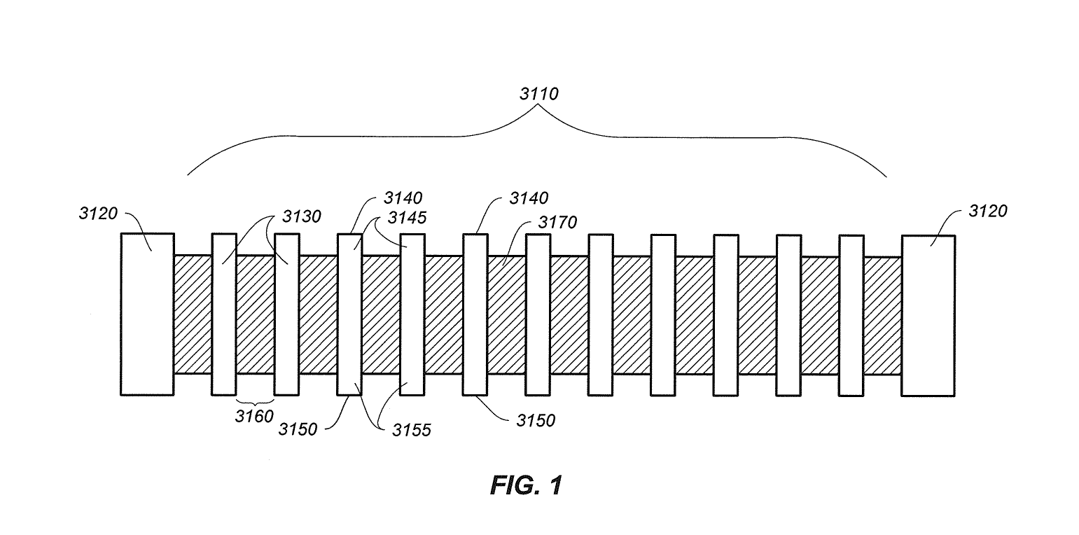

FIG. 1 is a simplified diagram showing a filled array of nanowires with protruding segments according to one embodiment of the present invention. This diagram is merely an example, which should not unduly limit the scope of the claims. One of ordinary skill in the art would recognize many variations, alternatives, and modifications. In FIG. 1, an array of nanowires 3110 is formed in a block of semiconductor material (e.g., a semiconductor substrate 3120). In one example, the semiconductor substrate 3120 is an entire wafer. In another example, the semiconductor substrate 3120 is a 4-inch wafer. In yet another example, the semiconductor substrate is a panel larger then a 4-inch wafer. In another example, the semiconductor substrate 3120 is a 6-inch wafer. In another example, the semiconductor substrate 3120 is an 8-inch wafer. In another example, the semiconductor substrate 3120 is a 12-inch wafer. In yet another example, the semiconductor substrate 3120 is a panel larger then a 12-inch wafer. In yet another example, the semiconductor substrate 3120 is in a shape other than that of a wafer. In yet another example, the semiconductor substrate 3120 is single-crystalline. In yet another example, the semiconductor substrate 3120 is poly-crystalline. In yet another example, the semiconductor substrate 3120 includes silicon.

In some embodiments, the semiconductor substrate 3120 is functionalized. For example, the semiconductor substrate 3120 is doped to form an n-type semiconductor. In another example, the semiconductor substrate 3120 is doped to form a p-type semiconductor. In yet another example, the semiconductor substrate 3120 is doped using Group III and/or Group V elements. In yet another example, the semiconductor substrate 3120 is functionalized to control the electrical and/or thermal properties of the semiconductor substrate 3120. In yet another example, the semiconductor substrate 3120 includes silicon doped with boron. In yet another example, the semiconductor substrate 3120 is doped to adjust the resistivity of the semiconductor substrate 3120 to between approximately 0.00001 Ω-m and 10 Ω-m. In yet another example, the semiconductor substrate 3120 is functionalized to provide the array of nanowires 3110 with a thermal conductivity between 0.1 W/(m·K) (i.e., Watts per meter per degree Kelvin) and 500 W/(m·K).

In other embodiments, the array of nanowires 3110 is formed in the semiconductor substrate 3120. For example, the array of nanowires 3110 is formed in substantially all of the semiconductor substrate 3120. In another example, the array of nanowires 3110 includes a plurality of nanowires 3130. In yet another example, each of the plurality of nanowires 3130 has an end 3140 and an end 3150. In yet another example, the ends 3150 of the plurality of nanowires 3130 collectively form an array area. In yet another example, the array area is 0.01 mm by 0.01 mm. In yet another example, the array area is 0.1 mm by 0.1 mm. In yet another example, the array area is 450 mm in diameter. In yet another example, a distance between each of the first ends 3140 of the plurality of nanowires 3130 and the second ends 3150 of each of the plurality of nanowires 3130 is at least 200 μm. In yet another example, the distance between each of the first ends 3140 of the plurality of nanowires 3130 and the second ends 3150 of each of the plurality of nanowires 3130 is at least 300 μm. In yet another example, the distance between each of the first ends 3140 of the plurality of nanowires 3130 and the second ends 3150 of each of the plurality of nanowires 3130 is at least 400 μm. In yet another example, the distance between each of the first ends 3140 of the plurality of nanowires 3130 and the second ends 3150 of each of the plurality of nanowires 3130 is at least 500 μm. In yet another example, the distance between each of the first ends 3140 of the plurality of nanowires 3130 and the second ends 3150 of each of the plurality of nanowires 3130 is at least 525 μm.

In yet another example, all the nanowires of the plurality of nanowires 3130 are substantially parallel to each other. In yet another example, the plurality of nanowires 3130 is formed substantially vertically in the semiconductor substrate 3120. In yet another example, the plurality of nanowires 3130 are oriented substantially perpendicular to the array area. In yet another example, each of the plurality of nanowires 3130 has a roughened surface. In yet another example, each of the plurality of nanowires 3130 includes a substantially uniform cross-sectional area with a large ratio of length to cross-sectional area. In yet another example, the cross-sectional area of each of the plurality of nanowires 3130 is substantially circular. In yet another example, the cross-sectional area of each of the plurality of nanowires 3130 is between 1 nm to 250 nm across.

In yet other embodiments, the plurality of nanowires 3130 have respective spacings 3160 between them. For example, each of the respective spacings 3160 is between 25 nm to 1000 nm across. In another example, the respective spacings 3160 are substantially filled with one or more fill materials 3170. In yet another example, the one or more fill materials 3170 form a matrix. In yet another example, the matrix is porous. In yet another example, the one or more fill materials 3170 have a low thermal conductivity. In yet another example, the thermal conductivity is between 0.0001 W/(m·K) and 50 W/(m·K). In yet another example, thermal conductivity is less than 1 W/(m·K). In yet another example, the one or more fill materials 3170 provide added mechanical stability to the plurality of nanowires 3130. In yet another example, the one or more fill materials are able to withstand temperatures in excess of 350° C. for extended periods of device operation. In yet another example, the one or more fill materials 3170 are able to withstand temperatures in excess of 550° C. for extended periods of device operation. In yet another example, the one or more fill materials 3170 are able to withstand temperatures in excess of 650° C. for extended periods of device operation. In yet another example, the one or more fill materials 3170 are able to withstand temperatures in excess of 750° C. In yet another example, the one or more fill materials 3170 are able to withstand temperatures in excess of 800° C. In yet another example, the one or more fill materials 3170 have a low coefficient of thermal expansion. In yet another example, the linear coefficient of thermal expansion is between 0.01 μm/m·K and 30 μm/m·K. In yet another example, the one or more fill materials 3170 are able to be planarized. In yet another example, the one or more fill materials 3170 are able to be polished. In yet another example, the one or more fill materials 3170 provide a support base for additional material overlying thereon. In yet another example, the one or more fill materials 3170 are conductive. In yet another example, the one or more fill materials 3170 support the formation of good electrical contacts with the plurality of nanowires 3130. In yet another example, the one or more fill materials 3170 support the formation of good thermal contacts with the plurality of nanowires 3130.

In yet other embodiments, the one or more fill materials 3170 each include at least one selected from a group consisting of photoresist, spin-on glass, spin-on dopant, aerogel, xerogel, and oxide, and the like. For example, the photoresist includes long UV wavelength G-line (e.g., approximately 436 nm) photoresist. In another example, the photoresist has negative photoresist characteristics. In yet another example, the photoresist exhibits good adhesion to various substrate materials, including Si, GaAs, InP, and glass. In yet another example, the photoresist exhibits good adhesion to various metals, including Au, Cu, and Al. In yet another example, the spin on glass has a high dielectric constant. In yet another example, the spin-on dopant includes n-type and/or p-type dopants. In yet another example, the spin-on dopant is applied regionally with different dopants in different areas of the array of nanowires 3110. In yet another example, the spin-on dopant includes boron and/or phosphorous and the like. In yet another example, the spin-on glass includes one or more spin-on dopants. In yet another example, the aerogel is derived from silica gel characterized by an extremely low thermal conductivity of about 0.1 W/(m·K) and lower. In yet another example, the one or more fill materials include long chains of one or more oxides. In yet another example, the one or more fill materials includes at least one selected from a group consisting of Al₂O₃, FeO, FeO₂, Fe₂O₃, TiO, TiO₂, ZrO₂, ZnO, HfO₂, CrO, Ta₂O₅, SiN, TiN, BN, SiO₂, AlN, CN, and/or the like.

According to some embodiments, the one or more fill materials 3170 do not completely fill the respective spacings 3160 between the plurality of nanowires 3130. In one example, the ends 3140 extend beyond the one or more fill materials 3170 to form protruding segments 3145. In another example, the ends 3150 extend beyond the one or more fill materials 3170 to form protruding segments 3155. In yet another example, the ends 3140, the ends 3150, and the one or more fill materials define three regions along the length of each of the plurality of nanowires. In yet another example, a region that extends from the ends 3140 to a surface of the one or more fill materials 3170 closest to the ends 3140 corresponds to the protruding segments 3145. In yet another example, another region that extends from the ends 3150 to another surface of the one or more fill materials 3170 corresponds to the protruding segments 3155. In yet another example, yet another region that extends between the surface and the another surface of the one or more fill materials 3170 corresponds to those portions of the plurality of nanowires 3130 that are not part of the protruding segments 3145 and the protruding segments 3155.

According to some embodiments, the array of nanowires 3110 embedded in the one or more fill materials 3170 has useful characteristics. For example, the embedded array of nanowires 3110 is well aligned. In another example, the embedded array of nanowires 3110 survives high temperature gradients without breaking. In yet another example, the embedded array of nanowires 3110 survives high temperature gradients without bending or breaking of the plurality of nanowires 3130. In yet another example, the enhanced mechanical strength of the embedded array of nanowires 3110 allows one or more surface polishing and/or planarization processes to be carried out on one or more surfaces of the embedded array of nanowires 3110. In yet another example, the enhanced mechanical strength of the embedded array of nanowires 3110 provides support for handling, machining, and/or manufacturing processes to be carried out on the embedded array of nanowires 3110. In yet another example, the protruding segments 3145 and/or the protruding segments 3155 support the formation of one or more electrical and/or one or more thermal contacts with the array of nanowires 3110.

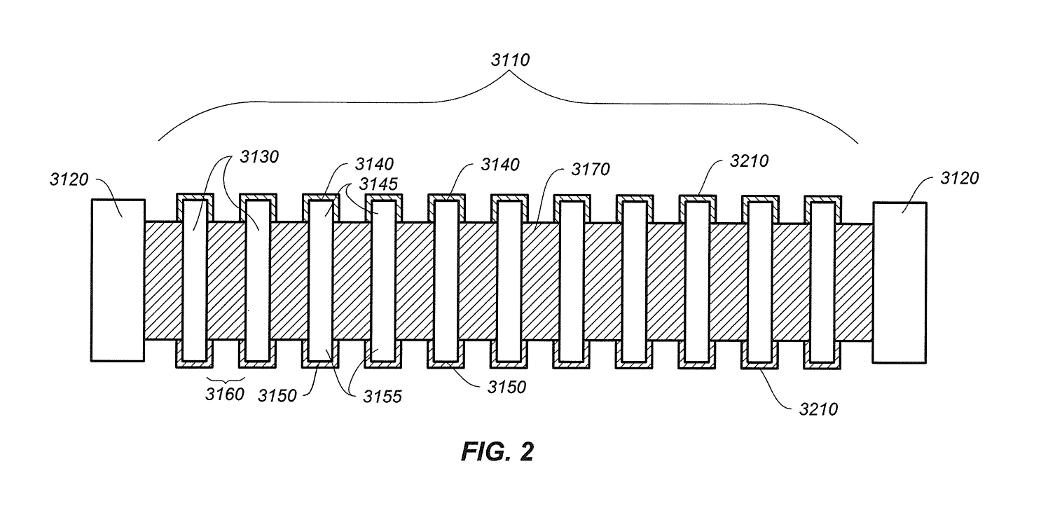

FIG. 2 is a simplified diagram showing a filled array of nanowires with protruding segments and contacts according to one embodiment of the present invention. This diagram is merely an example, which should not unduly limit the scope of the claims. One of ordinary skill in the art would recognize many variations, alternatives, and modifications. In FIG. 2, the array of nanowires 3110 further includes one or more contacts 3210. For example, each of the protruding segments 3145 is partially or completely covered with a respective one of the one or more contacts 3210. In another example, each of the protruding segments 3155 is partially or completely covered with a respective one of the one or more contacts 3210. In yet another example, the one or more contacts 3210 form a conformal coating on the protruding segments 3145 and/or the protruding segments 3155 respectively.

In some embodiments, the one or more contacts 3210 each include one or more conductive materials. For example, the one or more conductive materials include at least one selected from a group consisting of semiconductors, semi-metals, metals, and the like.

In another example, the semiconductors are each selected from a group consisting of Si, Ge, C, B, P, N, Ga, As, In, and the like. In yet another example, the semiconductors are doped. In yet another example, the semi-metals are selected from a group consisting of B, Ge, Si, Sn, and the like. In yet another example, the metals are selected from a group consisting of Ti, Al, Cu, Au, Ag, Pt, Ni, P, B, Cr, Li, W, Mg, TiW, TiNi, TiN, Mo, TiSi, MoSi, WSi, and the like. In yet another example, the one or more contacts 3210 include TiW in a 10 to 90 ratio. In yet another example, the one or more contacts 3210 include TiW in a 10 to 90 ratio and Ni.

In yet another example, the one or more contacts 3210 form one or more electric contacts with the ends 3140 and/or the ends 3150 of the plurality of nanowires 3130. In yet another example, the one or more contacts 3210 form one or more ohmic contacts with the ends 3140 and/or the ends 3150 of the plurality of nanowires 3130. In yet another example, the one or more contacts 3210 is configured to form one or more good thermal contacts with one or more surfaces for establishing one or more thermal paths through the one or more pluralities of the nanowire 3130 while limiting thermal leakage in the one or more fill materials 3170.

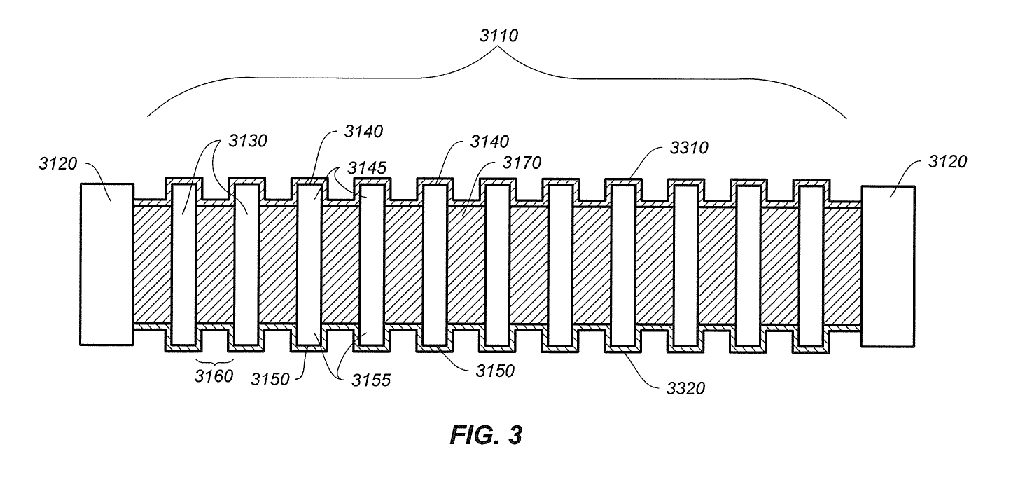

FIG. 3 is a simplified diagram showing a filled array of nanowires with protruding segments and contacts according to another embodiment of the present invention. This diagram is merely an example, which should not unduly limit the scope of the claims. One of ordinary skill in the art would recognize many variations, alternatives, and modifications. In FIG. 3, the array of nanowires 3110 further includes one or more contacts 3310 and/or one or more contacts 3320. For example, each of the protruding segments 3145 is covered by at least one contact selected from the one or more contacts 3310. In another example, each of the protruding segments 3155 is covered by at least one contact selected from the one or more contacts 3320. In yet another example, the one or more contacts 3310 form a conformal coating on the protruding segments 3145 and a surface of the one or more fill materials 3170. In yet another example, the one or more contacts 3320 form a conformal coating on the protruding segments 3155 and another surface of the one or more fill materials 3170.

In some embodiments, the one or more contacts 3310 and/or the one or more contacts 3320 each include one or more conductive materials. For example, the one or more conductive materials include at least one selected from a group consisting of semiconductors, semi-metals, metals, and the like. In another example, the semiconductors are each selected from a group consisting of Si, Ge, C, B, P, N, Ga, As, In, and the like. In yet another example, the semiconductors are doped. In yet another example, the semi-metals are selected from a group consisting of B, Ge, Si, Sn, and the like. In yet another example, the metals are selected from a group consisting of Ti, Al, Cu, Au, Ag, Pt, Ni, P, B, Cr, Li, W, Mg, TiW, TiNi, TiN, Mo, TiSi, MoSi, WSi, and the like. In yet another example, the one or more contacts 3310 and/or the one or more contacts 3320 include TiW in a 10 to 90 ratio. In yet another example, the one or more contacts 3310 and/or the one or more contacts 3320 include TiW in a 10 to 90 ratio and Ni.

In yet another example, the one or more contacts 3310 form one or more electric contacts with the ends 3140. In yet another example, the one or more contacts 3310 form one or more ohmic contacts with the ends 3140. In yet another example, the one or more contacts 3320 form one or more electric contacts with the ends 3150. In yet another example, the one or more contacts 3320 form one or more ohmic contacts with the ends 3150. In yet another example, the one or more contacts 3310 and/or the one or more contacts 3320 are configured to form one or more good thermal contacts with one or more surfaces for establishing one or more thermal paths through the one or more pluralities of the nanowire 3130 while limiting thermal leakage in the one or more fill materials 3170.

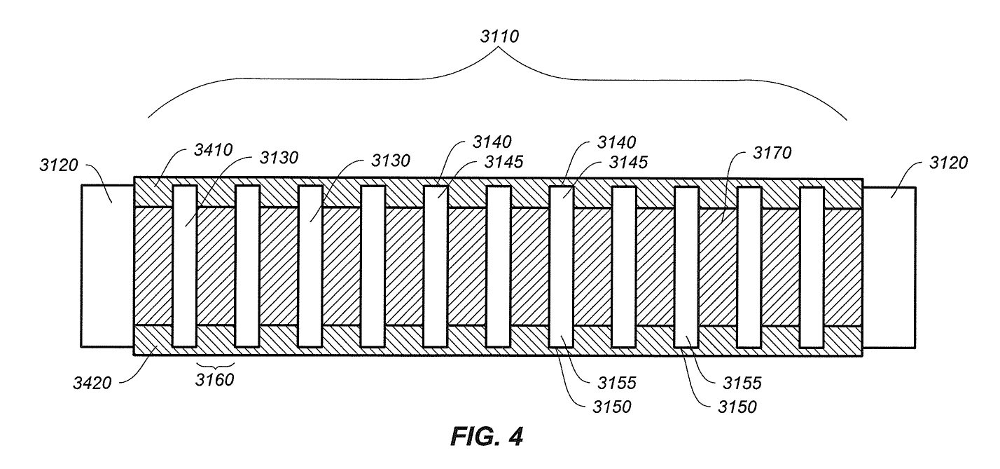

FIG. 4 is a simplified diagram showing a filled array of nanowires with protruding segments and contacts according to another embodiment of the present invention. This diagram is merely an example, which should not unduly limit the scope of the claims. One of ordinary skill in the art would recognize many variations, alternatives, and modifications. In FIG. 4, the array of nanowires 3110 further includes one or more contacts 3410 and/or one or more contacts 3420. For example, each of the protruding segments 3145 is covered by at least one contact selected from the one or more contacts 3410. In another example, each of the protruding segments 3155 is covered by at least one of the contacts selected from the one or more contacts 3420.

In some embodiments, the one or more contacts 3410 and/or the one or more contacts 3420 each include one or more conductive materials. For example, the one or more conductive materials include at least one selected from a group consisting of semiconductors, semi-metals, metals, and the like. In another example, the semiconductors are each selected from a group consisting of Si, Ge, C, B, P, N, Ga, As, In, and the like. In yet another example, the semiconductors are doped. In yet another example, the semi-metals are selected from a group consisting of B, Ge, Si, Sn, and the like. In yet another example, the metals are selected from a group consisting of Ti, Al, Cu, Au, Ag, Pt, Ni, P, B, Cr, Li, W, Mg, TiW, TiNi, TiN, Mo, TiSi, MoSi, WSi, and the like. In yet another example, the one or more contacts 3410 and/or the one or more contacts 3420 include TiW in a 10 to 90 ratio. In yet another example, the one or more contacts 3410 and/or the one or more contacts 3420 include TiW in a 10 to 90 ratio and Ni. In yet another example, a TiW layer is about 5000 Å thick. In yet another example, a Ni layer is about 5000 Å thick.

In yet another example, the one or more contacts 3410 form one or more electric contacts with the ends 3140. In yet another example, the one or more contacts 3410 form one or more ohmic contacts with the ends 3140. In yet another example, the one or more contacts 3420 form one or more electric contacts with the ends 3150. In yet another example, the one or more contacts 3420 form one or more ohmic contacts with the ends 3150. In yet another example, the one or more contacts 3410 and/or the one or more contacts 3420 are configured to form one or more good thermal contacts with one or more surfaces for establishing one or more thermal paths through the one or more pluralities of the nanowire 3130 while limiting thermal leakage in the one or more fill materials 3170.

As discussed above and further emphasized here, FIGS. 1-4 are merely examples, which should not unduly limit the scope of the claims. One of ordinary skill in the art would recognize many variations, alternatives, and modifications. In some embodiments, nanostructures other than nanowires are formed. For example, nanoholes are formed in the semiconductor substrate. In another example, the nanoholes are at least partially filled with one or fill materials. In yet another example, the surfaces of the nanoholes form protruding segments that are covered by one or more contacts. In yet another example, nanotubes and/or nanomeshes are formed in the semiconductor substrate. In certain embodiments, more than one array of nanostructures is formed in a semiconductor substrate. For example, one or more arrays of nanowires is formed in the semiconductor substrate. In certain embodiments, the array of nanowires has protruding segments that extend only on one side. For example, the array of nanowires 3110 in FIGS. 1-4 only have protruding segments 3145 and not protruding segments 3155. In another example, the array of nanowires 3110 has neither protruding segments 3145 nor protruding segments 3155.

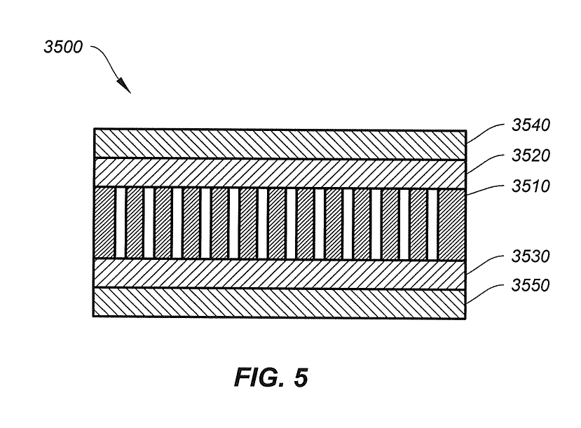

FIG. 5 is a simplified diagram showing an array of nanostructures with contacts and electrodes according to one embodiment of the present invention. This diagram is merely an example, which should not unduly limit the scope of the claims. One of ordinary skill in the art would recognize many variations, alternatives, and modifications. For example, the array of nanostructures with contacts and electrodes 3500 is configured for use in a thermoelectric device. In another example, the array of nanostructures with contacts and electrodes 3500 is formed around an array of nanostructures 3510. For example, the array of nanostructures 3510 is the array of nanowires 3110 as shown in FIGS. 1-4. In another example, the array of nanostructures 3510 is at least partially filled. In yet another example, the array of nanostructures 3510 is placed between one or more contacts 3520 and one or more contacts 3530. In yet another example, the one or more contacts 3520 are the one or more contacts 3210, the one or more contacts 3310, the one or more contacts 3320, the one or more contacts 3410, and/or the one or more contacts 3420. In yet another example, the one or more contacts 3530 are the one or more contacts 3210, the one or more contacts 3320, the one or more contacts 3310, the one or more contacts 3420, and/or the one or more contacts 3410. In yet another example, one or more electrodes 3540 are placed on the one or more contacts 3520. In yet another example, one or more electrodes 3550 are placed on the one or more contacts 3530.

According to some embodiments, the one or more electrodes 3540 and/or the one or more electrodes 3550 each include one or more conductive materials. For example, the one or more conductive materials include at least one selected from a group consisting of Ti, Al, Cu, Au, Ag, Pt, Ni, P, B, Cr, Li, W, Mg, TiW, TiNi, TiN, Mo, TiSi, MoSi, NiSi, WSi, and the like. In yet another example, the one or more electrodes 3540 and/or the one or more electrodes 3550 include TiW in a 10 to 90 ratio. In yet another example, the one or more electrodes 3540 and/or the one or more electrodes 3550 include TiW in a 10 to 90 ratio and Ni. In yet another example, a TiW layer is about 5000 Å thick. In yet another example, a Ni layer is about 5000 Å thick.

As discussed above and further emphasized here, FIG. 5 is merely an example, which should not unduly limit the scope of the claims. One of ordinary skill in the art would recognize many variations, alternatives, and modifications. In some embodiments, nanostructures other than nanowires are formed. For example, the one or more contacts 3520 is omitted. In another example, the one or more contacts 3530 is omitted. In yet another example, the array of nanostructures 3510 is placed between the one or more electrodes 3540 and the one or more electrodes 3550.

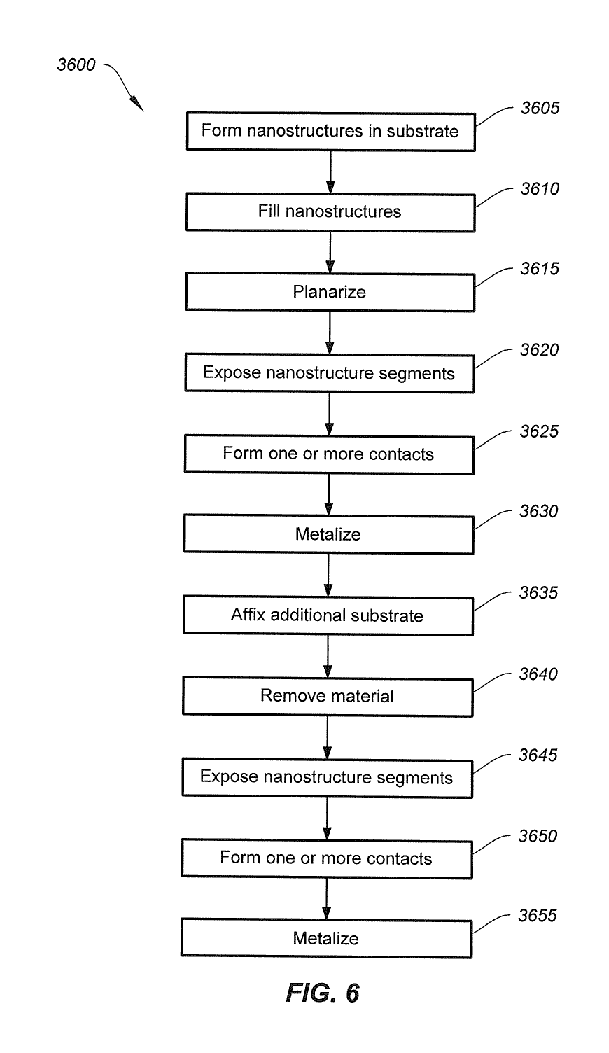

FIG. 6 is a simplified diagram showing a method for forming a filled array of nanostructures with protruding segments, contacts, and electrodes according to one embodiment of the present invention. This diagram is merely an example, which should not unduly limit the scope of the claims. One of ordinary skill in the art would recognize many variations, alternatives, and modifications. The method 3600 includes a process 3605 for forming an array of nanostructures in a substrate, a process 3610 for filling the array of nanostructures, a process 3615 for planarizing the filled array of nanostructures, a process 3620 for exposing segments of the nanostructures, a process 3625 for forming one or more contacts on the exposed segments of the nanostructures, a process 3630 for forming one or more electrodes using metalization, a process 3635 for affixing an additional substrate, a process 3640 for removing material, a process 3645 for exposing segments of the nanostructures, a process 3650 for forming one or more contacts on the exposed segments of the nanostructures, and a process 3655 for forming one or more electrodes using metalization. For example, the method 3600 is used to form the plurality of nanostructures with contacts and electrodes 3500 as shown in FIG. 5. In yet another example, the processes 3615, 3625, 3635, and/or 3650 are skipped.

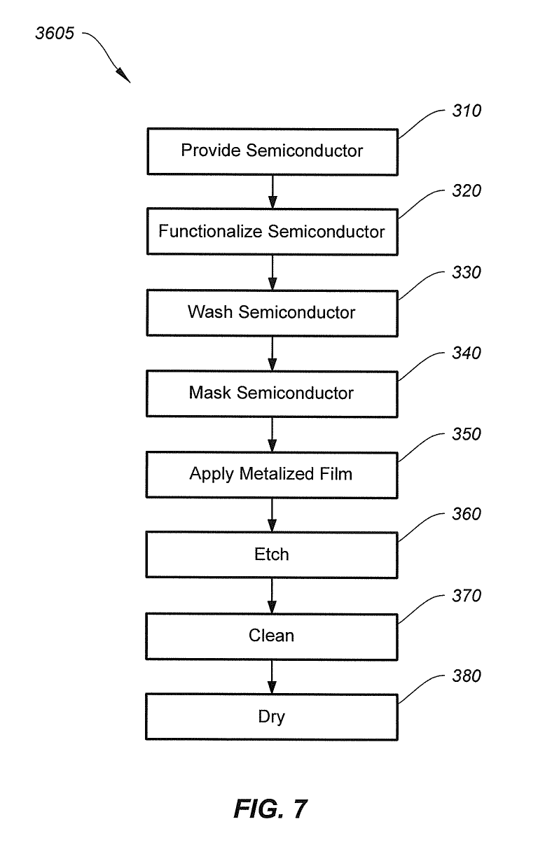

FIG. 7 is a simplified diagram showing the process 3605 for forming an array of nanostructures in a substrate as part of the method 3600 for forming an array of nanostructures with protruding segments, contacts, and electrodes according to one embodiment of the present invention. This diagram is merely an example, which should not unduly limit the scope of the claims. One of ordinary skill in the art would recognize many variations, alternatives, and modifications. The process 3605 includes a process 310 for providing the semiconductor substrate, a process 320 for functionalizing the semiconductor substrate, a process 330 for washing the semiconductor substrate, a process 340 for masking portions of the semiconductor substrate, a process 350 for applying a metalized film to the semiconductor substrate, a process 360 for etching the semiconductor substrate, a process 370 for cleaning the etched semiconductor substrate, and a process 380 for drying the etched semiconductor substrate.

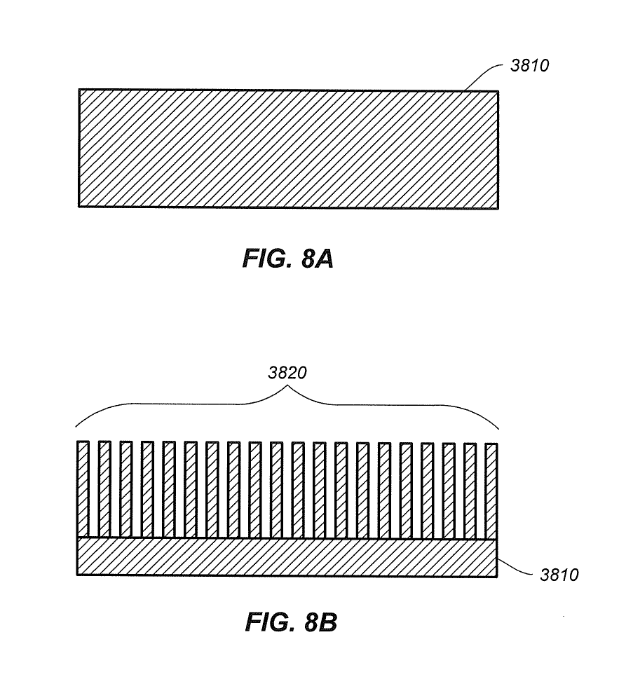

FIG. 8A is a simplified diagram showing a substrate used for the process 310 for providing a substrate as part of the method 3600 for forming an array of nanostructures with protruding segments, contacts, and electrodes according to one embodiment of the present invention. This diagram is merely an example, which should not unduly limit the scope of the claims. One of ordinary skill in the art would recognize many variations, alternatives, and modifications. For example, the substrate 3810 is a block of semiconductor material (e.g., a semiconductor substrate). In another example, the semiconductor substrate 3810 is an entire wafer. In yet another example, the semiconductor substrate 3810 is a 4-inch wafer. In yet another example, the semiconductor substrate is a panel larger then a 4-inch wafer. In another example, the semiconductor substrate 3810 is a 6-inch wafer. In another example, the semiconductor substrate 3810 is an 8-inch wafer. In another example, the semiconductor substrate 3810 is a 12-inch wafer. In yet another example, the semiconductor substrate 3810 is a panel larger then a 12-inch wafer. In yet another example, the semiconductor substrate 3810 is in a shape other than that of a wafer. In yet another example, the semiconductor substrate 3810 is single-crystalline. In yet another example, the semiconductor substrate 3810 is poly-crystalline. In yet another example, the semiconductor substrate 3810 includes silicon.

In some embodiments, the semiconductor substrate 3810 is functionalized. For example, the semiconductor substrate 3810 is doped to form an n-type semiconductor. In another example, the semiconductor substrate 3810 is doped to form a p-type semiconductor. In yet another example, the semiconductor substrate 3810 is doped using Group III and/or Group V elements. In yet another example, the semiconductor substrate 3810 is functionalized to control the electrical and/or thermal properties of the semiconductor substrate 3810. In yet another example, the semiconductor substrate 3810 includes silicon doped with boron. In yet another example, the semiconductor substrate 3810 is doped to adjust the resistivity of the semiconductor substrate 3810 to between approximately 0.00001 Ω-m and 10 Ω-m. In yet another example, the semiconductor substrate 3810 is functionalized to adjust the thermal conductivity between 0.1 W/(m·K) (i.e., Watts per meter per degree Kelvin) and 500 W/(m·K).

FIG. 8B is a simplified diagram showing an array of nanostructures in a substrate as formed by the process 3605 as shown in FIG. 7 as part of the method 3600 for forming an array of nanostructures with protruding segments, contacts, and electrodes according to one embodiment of the present invention. This diagram is merely an example, which should not unduly limit the scope of the claims. One of ordinary skill in the art would recognize many variations, alternatives, and modifications. For example, the array of nanostructures 3820 is formed using the process 3605. In another example, the array of nanostructures 3820 is the array of nanowires 3110 as shown in FIGS. 1-4. In yet another example, the array of nanostructures 3820 is the array of nanostructures 3510 as shown in FIG. 5. In yet another example, the array of nanostructures 3820 is an array of nanoholes. In yet another example, the array of nanostructures 3820 is an array of nanotubes. In yet another example, the array of nanostructures 3820 is a nanomesh.

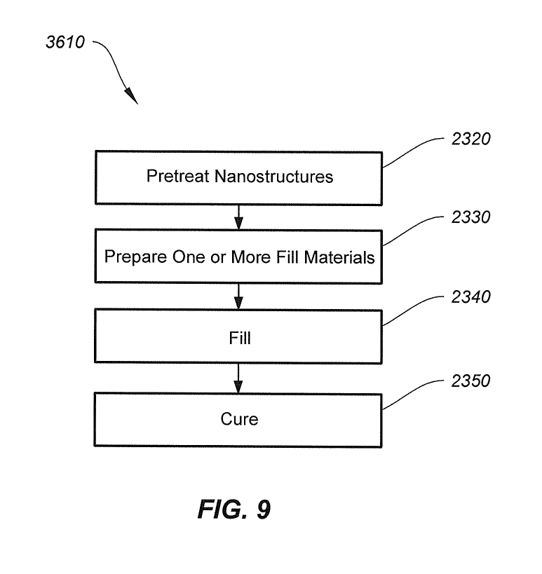

FIG. 9 is a simplified diagram showing the process 3610 for filling the array of nanostructures in a substrate as part of the method 3600 for forming an array of nanostructures with protruding segments, contacts, and electrodes according to one embodiment of the present invention. This diagram is merely an example, which should not unduly limit the scope of the claims. One of ordinary skill in the art would recognize many variations, alternatives, and modifications. The process 3610 includes a process 2320 for pretreating the array of nanostructures, a process 2330 for preparing one or more fill materials, a process 2340 for filling the array of nanostructures, and a process 2350 for curing the one or more fill materials. For example, the process 3610 is used to at least partially fill the array of nanowires 3110 as shown in FIGS. 1-4. In another example, the process 3610 is used to at least partially fill the array of nanostructures 3510 as shown in FIG. 5. In yet another example, the process 3610 forms the one or more fill materials 3170 as shown in FIGS. 1-4. In yet another example, the process 3610 is used to fill an array of nanoholes, an array of nanotubes, and/or a nanomesh. In yet another example, the processes 2320 and/or 2350 are skipped.

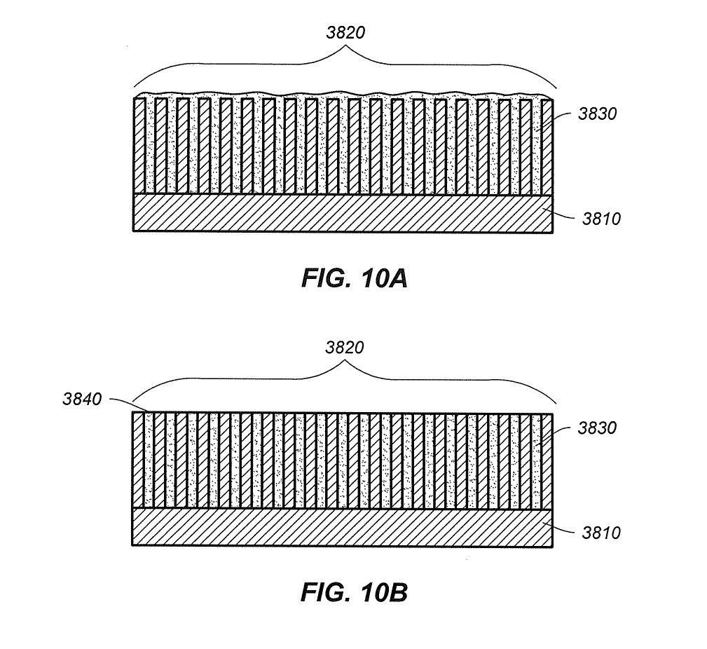

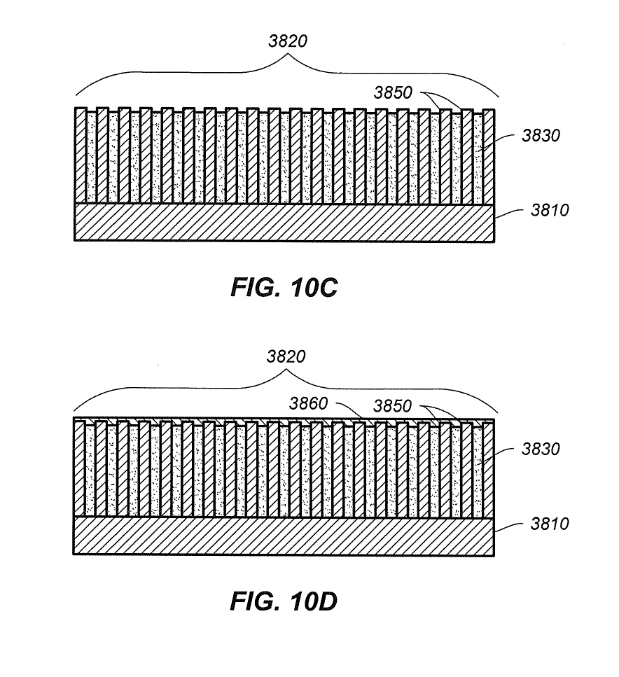

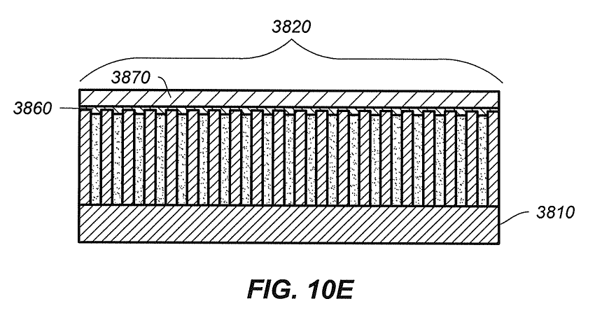

FIG. 10A is a simplified diagram of a filled array of nanostructures in a substrate as formed by the process 3610 of FIG. 9 as part of the method 3600 for forming an array of nanostructures with protruding segments, contacts, and electrodes according to one embodiment of the present invention. This diagram is merely an example, which should not unduly limit the scope of the claims. One of ordinary skill in the art would recognize many variations, alternatives, and modifications. For example, the array of nanostructures 3820 as formed in the substrate 3810 is filled with one or more fill materials 3830. In another example, the one or more fill materials 3830 are the one or more fill materials 3170. In yet another example, the one or more fill materials 3830 each include at least one selected from a group consisting of photoresist, spin-on glass, spin-on dopant, aerogel, xerogel, and oxide, and the like. For example, the photoresist includes long UV wavelength G-line (e.g., approximately 436 nm) photoresist. In another example, the photoresist has negative photoresist characteristics. In yet another example, the photoresist exhibits good adhesion to various substrate materials, including Si, GaAs, InP, and glass. In yet another example, the photoresist exhibits good adhesion to various metals, including Au, Cu, and Al. In yet another example, the spin on glass has a high dielectric constant. In yet another example, the spin-on dopant includes n-type and/or p-type dopants. In yet another example, the spin-on dopant is applied regionally with different dopants in different areas of the array of nanowires 3820. In yet another example, the spin-on dopant includes boron and/or phosphorous and the like. In yet another example, the spin-on glass includes one or more spin-on dopants. In yet another example, the aerogel is derived from silica gel characterized by an extremely low thermal conductivity of about 0.1 W/(m·K) and lower. In yet another example, the one or more fill materials include long chains of one or more oxides. In yet another example, the one or more fill materials includes at least one selected from a group consisting of Al₂O₃, FeO, FeO₂, Fe₂O₃, TiO, TiO₂, ZrO₂, ZnO, HfO₂, CrO, Ta₂O₅, SiN, TiN, BN, SiO₂, MN, CN, and/or the like.

FIG. 10B is a simplified diagram of a filled and planarized array of nanostructures in a substrate as formed by the planarization process 3615 as part of the method 3600 for forming an array of nanostructures with protruding segments, contacts, and electrodes according to one embodiment of the present invention. This diagram is merely an example, which should not unduly limit the scope of the claims. One of ordinary skill in the art would recognize many variations, alternatives, and modifications. For example, at the optional process 3615 the filled array of nanostructures 3820 is planarized. In another example, at least one surface of the filled array of nanostructures 3820 is made substantially planar. In yet another example, the planarization process 3615 exposes ends of the array of nanostructures 3820. In yet another example, the planarization process 3615 includes at least one process selected from a group consisting of plasma etching, wet chemical etching, lapping, mechanical polishing, chemical mechanical polishing, spontaneous dry etching, and the like. In yet another example, the lapping process includes the use of a 6 μm diamond slurry with a copper base plate. In yet another example, the plasma etching uses SF₆ in a vacuμm chamber. In yet another example, the spontaneous dry etching uses XeF₂ planarization process 3615 includes plasma etching. In yet another example, the planarization process 3615 prepares the filled array of nanostructures 3820 for further handling, machining, and/or manufacturing processes.

FIG. 10C is a simplified diagram of a filled and planarized array of nanostructures with exposed segments as formed by the process 3620 for exposing nanostructure segments as part of the method 3600 for forming an array of nanostructures with protruding segments, contacts, and electrodes according to one embodiment of the present invention. This diagram is merely an example, which should not unduly limit the scope of the claims. One of ordinary skill in the art would recognize many variations, alternatives, and modifications. For example, at the process 3620, exposed segments 3850 for each of the nanostructures in the array of nanostructures 3820 are formed. In another example, the exposed segments 3850 are the protruding segments 3145 as shown in FIG. 1. In yet another example, the process 3620 for exposing the segments of the nanostructures includes removing a portion of the one or more fill materials 3830. In yet another example, the process 3620 for exposing the segments of the nanostructures includes etching using a HF solution. In yet another example, the HF solution includes at least one selected from a group consisting of a buffering agent, a surfactant, and other additives. In yet another example, the process 3620 for exposing the segments of the nanostructures includes etching in a reactive ion etcher.

FIG. 10D is a simplified diagram of the array of nanostructures with one or more contacts on the exposed segments of the nanostructures as formed by the process 3625 for forming one or more contacts as part of the method 3600 for forming an array of nanostructures with protruding segments, contacts, and electrodes according to one embodiment of the present invention. This diagram is merely an example, which should not unduly limit the scope of the claims. One of ordinary skill in the art would recognize many variations, alternatives, and modifications. For example, at the optional process 3625, the exposed segments 3850 of the nanostructures have one or more contacts 3860 formed thereon. In another example, the one or more contacts 3860 are the one or more contacts 3410 as shown in FIG. 4. In yet another example, the process 3625 for forming the one or more contacts includes at least one process selected from a group consisting of electrolytic plating, electroless plating, evaporation, sputtering, molecular beam epitaxy, chemical vapor deposition, atomic layer deposition, and the like.

In yet another example, the one or more contacts 3860 each include one or more conductive materials. For example, the one or more conductive materials include at least one selected from a group consisting of semiconductors, semi-metals, metals, and the like. In another example, the semiconductors are each selected from a group consisting of Si, Ge, C, B, P, N, Ga, As, In, and the like. In yet another example, the semiconductors are doped. In yet another example, the semi-metals are selected from a group consisting of Be, Ge, Si, Sn, and the like. In yet another example, the metals are selected from a group consisting of Ti, Al, Cu, Au, Ag, Pt, Ni, P, B, Cr, Li, W, Mg, TiW, TiNi, TiN, Mo, TiSi, MoSi, WSi, and the like. In yet another example, the one or more contacts 3860 include TiW in a 10 to 90 ratio. In yet another example, the one or more contacts 3860 include TiW in a 10 to 90 ratio and Ni. In yet another example, a TiW layer is about 5000 Å thick. In yet another example, a Ni layer is about 5000 Å thick.

In yet another example, the one or more contacts 3860 form one or more electric contacts with the segments 3850. In yet another example, the one or more contacts 3860 form one or more ohmic contacts with the segments 3850. In yet another example, the one or more contacts 3860 are configured to form one or more good thermal contacts with one or more surfaces for establishing one or more thermal paths through the array of nanostructures 3820 while limiting thermal leakage in the one or more fill materials 3830.

As discussed above and further emphasized here, FIG. 10D is merely an example, which should not unduly limit the scope of the claims. One of ordinary skill in the art would recognize many variations, alternatives, and modifications. In some embodiments, different styles of contacts are formed on the exposed segments 3850 of the nanostructures. For example, each of the exposed segments 3850 is covered by a respective one of the one or more contacts as shown in FIG. 2. In another example, the one or more contacts form a conformal coating on the exposed segments 3850 and the one or more fill materials 3830 as shown in FIG. 3. In some embodiments, different areas of the array of nanostructures 3820 are covered by different contacts that are not contiguous with each other. For example, a plurality of the exposed segments 3850 are covered by a contact selected from the one or more contacts 3860. In another example, another plurality of the exposed segments 3850 are covered by another contact selected from the one or more contacts 3860. In yet another example, the contact and the another contact are not contiguous with each other and they are formed by the same or different materials.

FIG. 10E is a simplified diagram of the array of nanostructures with one or more electrodes on the one or more contacts as formed by the process 3630 for metalization as part of the method 3600 for forming an array of nanostructures with protruding segments, contacts, and electrodes according to one embodiment of the present invention. This diagram is merely an example, which should not unduly limit the scope of the claims. One of ordinary skill in the art would recognize many variations, alternatives, and modifications. According to some embodiments, at the process 3630, metalization is used to form one or more electrodes 3870 on the one or more contacts 3860. For example, the one or more electrodes 3870 are the one or more electrodes 3540. In another example, the metalization process 3630 includes at least one process selected from a group consisting of electrolytic plating, electroless plating, evaporation, sputtering, molecular beam epitaxy, chemical vapor deposition, atomic layer deposition, and the like. In yet another example, the chemical vapor deposition occurs at low pressure. In yet another example, the chemical vapor deposition is plasma enhanced. In yet another example, the one or more electrodes 3870 each include one or more conductive materials. For example, the one or more conductive materials include at least one selected from a group consisting of Ti, Al, Cu, Au, Ag, Pt, Ni, P, B, Cr, Li, W, Mg, TiW, TiNi, TiN, Mo, TiSi, MoSi, NiSi, WSi, and the like. In yet another example, the one or more electrodes 3870 include TiW in a 10 to 90 ratio. In yet another example, the one or more electrodes 3870 include TiW in a 10 to 90 ratio and Ni. In yet another example, a TiW layer is about 5000 Å thick. In yet another example, a Ni layer is about 5000 Å thick.

As discussed above and further emphasized here, FIG. 10E is merely an example, which should not unduly limit the scope of the claims. One of ordinary skill in the art would recognize many variations, alternatives, and modifications. In some embodiments, the one or more electrodes are formed in place of the one or more contacts. For example, the one or more electrodes are formed directly on the one or more fill materials and/or the exposed segments of the nanostructures.

As discussed above and further emphasized here, FIGS. 10A-10E are merely examples, which should not unduly limit the scope of the claims. One of ordinary skill in the art would recognize many variations, alternatives, and modifications. In some embodiments, the process 3610 for filling the array of nanostructures includes forming the one or more fill materials in layers.

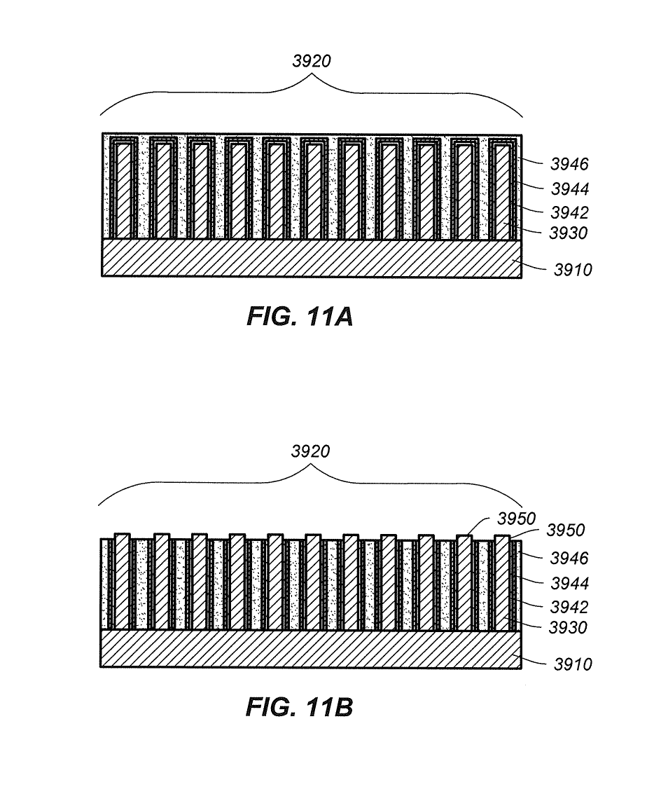

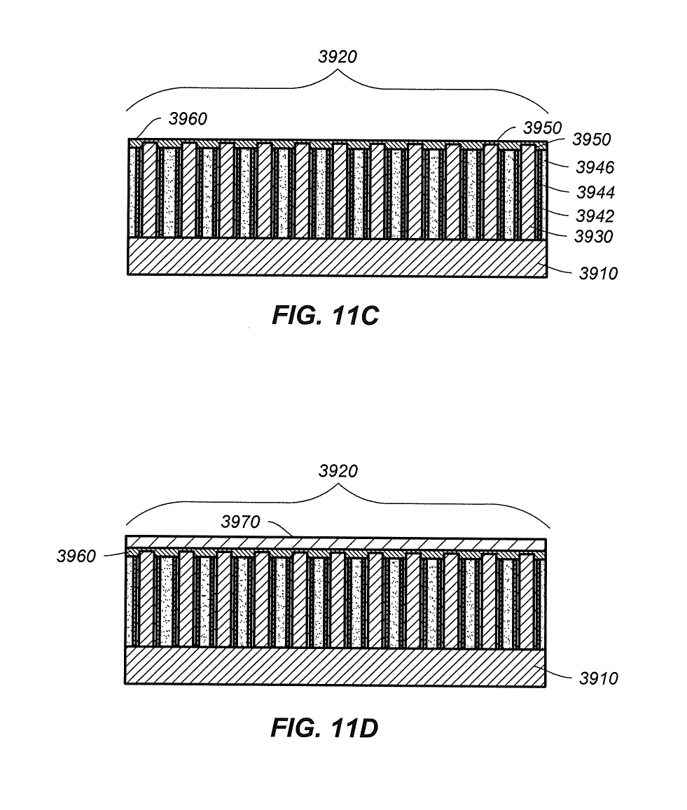

FIG. 11A is a simplified diagram showing a filled array of nanostructures in a substrate as formed as part of the process 3610 of FIG. 9 as part of the method 3600 for forming an array of nanostructures with protruding segments, contacts, and electrodes according to another embodiment of the present invention. This diagram is merely an example, which should not unduly limit the scope of the claims. One of ordinary skill in the art would recognize many variations, alternatives, and modifications. As shown in FIG. 11A, one or more fill materials is distributed throughout the array of nanostructures 3920 in a layered fashion. For example, at least a first fill material is deposited in a first fill layer 3942 on the one or more surfaces of the plurality of nanostructures 3930. In another example, at least a second fill material is deposited in a second fill layer 3944 on the first fill layer 3942. In yet another example, at least a third fill material is deposited in a third fill layer 3946 on the second fill layer 3944. In yet another example, the first fill layer 3942, the second fill layer 3944, and/or the third fill layer 3946 form a conformal coating on the material in the layer below it. In yet another example, the first fill layer 3942 provides one or more surfaces with a hydrophobicity that is different from the underlying surfaces of the plurality of nanostructures 3930. In yet another example, the first fill layer 3942 provides thermal protection to the underlying the plurality of nanostructures 3930. In yet another example, the first fill material is SiN, TiN, BN, MN, and/or CN, and the like. In yet another example, the second fill material and the third fill material are two dissimilar oxides. In yet another example, the second fill material is SiO₂ and/or ZrO₂. In yet another example, the third fill material is ZrO₂ and/or SiO₂.

As discussed above and further emphasized here, FIG. 11A is merely an example, which should not unduly limit the scope of the claims. One of ordinary skill in the art would recognize many variations, alternatives, and modifications. For example, nanostructures other than nanowires are filled. In another example, more than three layers of the one or more fill materials are used to fill the array of nanostructures 3920. In yet another example, the at least second fill material and the at least third fill material are deposited in alternating layers until the array of nanostructures 3920 is substantially filled. In yet another example, different combinations of the one or more fill materials are used in different regions of the array of nanostructures 3920. In yet another example, different combinations of the one or more fill materials having at least two distinct phases are used to fill the array of nanostructures 3920.

FIG. 11B is a simplified diagram of a filled and planarized array of nanostructures with exposed segments as formed by the process 3620 for exposing the nanostructure segments as part of the method 3600 for forming an array of nanostructures with protruding segments, contacts, and electrodes according to another embodiment of the present invention. This diagram is merely an example, which should not unduly limit the scope of the claims. One of ordinary skill in the art would recognize many variations, alternatives, and modifications. For example, at the process 3620, exposed segments 3950 for each of the nanostructures 3930 in the array of nanostructures 3920 are formed. In another example, the exposed segments 3950 are the protruding segments 3145 as shown in FIG. 1. In yet another example, the process 3620 for exposing the segments of the nanostructures includes removing a portion of the one or more fill materials 3942, 3944, and/or 3946. In yet another example, the process 3620 for exposing the segments of the nanostructures includes etching using a HF solution. In yet another example, the HF solution includes at least one selected from a group consisting of a buffering agent, a surfactant, and other additives.

FIG. 11C is a simplified diagram of the array of nanostructures with one or more contacts on the exposed segments of the nanostructures as formed by the process 3625 for forming one or more contacts as part of the method 3600 for forming an array of nanostructures with protruding segments, contacts, and electrodes according to one embodiment of the present invention. This diagram is merely an example, which should not unduly limit the scope of the claims. One of ordinary skill in the art would recognize many variations, alternatives, and modifications. For example, at the optional process 3625, the exposed segments 3950 of the nanostructures have one or more contacts 3960 formed thereon. In another example, the one or more contacts 3960 are the one or more contacts 3410 as shown in FIG. 4. In yet another example, the one or more contacts 3960 each include one or more conductive materials. For example, the one or more conductive materials include at least one selected from a group consisting of semiconductors, semi-metals, metals, and the like. In another example, the semiconductors are each selected from a group consisting of Si, Ge, C, B, P, N, Ga, As, In, and the like. In yet another example, the semiconductors are doped. In yet another example, the semi-metals are selected from a group consisting of B, Ge, Si, Sn, and the like. In yet another example, the metals are selected from a group consisting of Ti, Al, Cu, Au, Ag, Pt, Ni, P, B, Cr, Li, W, Mg, TiW, TiNi, TiN, Mo, TiSi, MoSi, WSi, and the like. In yet another example, the one or more contacts 3960 include TiW in a 10 to 90 ratio. In yet another example, the one or more contacts 3960 include TiW in a 10 to 90 ratio and Ni. In yet another example, a TiW layer is about 5000 Å thick. In yet another example, a Ni layer is about 5000 Å thick.

In yet another example, the one or more contacts 3960 form one or more electric contacts with the segments 3950. In yet another example, the one or more contacts 3960 form one or more ohmic contacts with the segments 3950. In yet another example, the one or more contacts 3860 are configured to form one or more good thermal contacts with one or more surfaces for establishing one or more thermal paths through the array of nanostructures 3920 while limiting thermal leakage in the one or more fill materials 3942, 3944, and/or 3946.

As discussed above and further emphasized here, FIG. 11C is merely an example, which should not unduly limit the scope of the claims. One of ordinary skill in the art would recognize many variations, alternatives, and modifications. In some embodiments, different styles of contacts are formed on the exposed segments 3950 of the nanostructures. For example, each of the exposed segments 3950 is covered by a respective one of the one or more contacts as shown in FIG. 2. In another example, the one or more contacts form a conformal coating on the exposed segments 3950 and the one or more fill materials 3942, 3944, and/or 3946 as shown in FIG. 3. In some embodiments, different areas of the array of nanostructures 3920 are covered by different contacts that are not contiguous with each other. For example, a plurality of the exposed segments 3950 are covered by a contact selected from the one or more contacts 3960. In another example, another plurality of the exposed segments 3950 are covered by another contact selected from the one or more contacts 3960. In yet another example, the contact and the another contact are not contiguous with each other and they are formed by the same or different materials.

FIG. 11D is a simplified diagram of the array of nanostructures with one or more electrodes on the one or more contacts as formed by the metalization process 3630 as part of the method 3600 for forming an array of nanostructures with protruding segments, contacts, and electrodes according to one embodiment of the present invention. This diagram is merely an example, which should not unduly limit the scope of the claims. One of ordinary skill in the art would recognize many variations, alternatives, and modifications. According to some embodiments, at the process 3630, metalization is used to form one or more electrodes 3970 on the one or more contacts 3960. For example, the one or more electrodes 3970 are the one or more electrodes 3540. In another example, the metalization process 3630 includes at least one process selected from a group consisting of electrolytic plating, electroless plating, evaporation, sputtering, molecular beam epitaxy, chemical vapor deposition, atomic layer deposition, and the like. In yet another example, the chemical vapor deposition occurs at low pressure. In yet another example, the chemical vapor deposition is plasma enhanced. In yet another example, the one or more electrodes 3970 each include one or more conductive materials. For example, the one or more conductive materials include at least one selected from a group consisting of Ti, Al, Cu, Au, Ag, Pt, Ni, P, B, Cr, Li, W, Mg, TiW, TiNi, TiN, Mo, TiSi, MoSi, NiSi, WSi, and the like. In yet another example, the one or more electrodes 3970 include TiW in a 10 to 90 ratio. In yet another example, the one or more electrodes 3970 include TiW in a 10 to 90 ratio and Ni. In yet another example, a TiW layer is about 5000 Å thick. In yet another example, a Ni layer is about 5000 Å thick.

As discussed above and further emphasized here, FIG. 11D is merely an example, which should not unduly limit the scope of the claims. One of ordinary skill in the art would recognize many variations, alternatives, and modifications. In some embodiments, the one or more electrodes are formed in place of the one or more contacts. For example, the one or more electrodes are formed directed on the one or more fill materials and/or the exposed segments of the nanostructures.

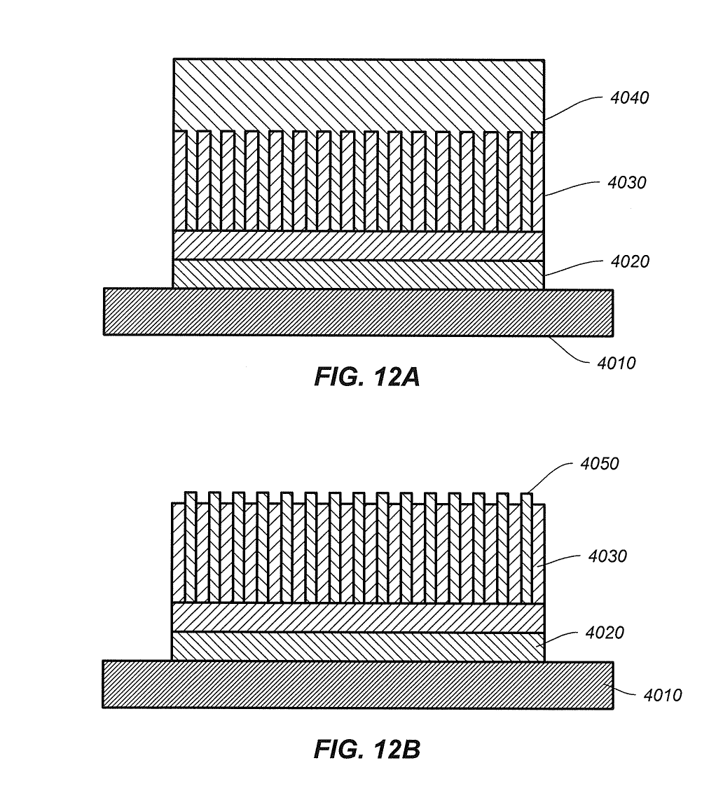

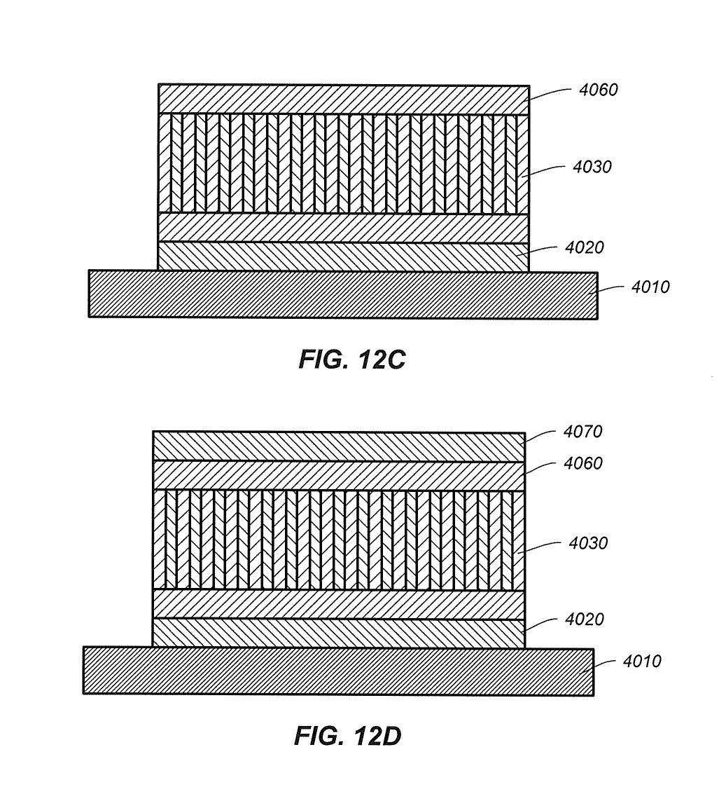

FIG. 12A is a simplified diagram of the array of nanostructures with one or more electrodes affixed to an additional substrate as formed by the process 3635 for affixing an additional substrate as part of the method 3600 for forming an array of nanostructures with protruding segments, contacts, and electrodes according to one embodiment of the present invention. This diagram is merely an example, which should not unduly limit the scope of the claims. One of ordinary skill in the art would recognize many variations, alternatives, and modifications. According to some embodiments, at the optional process 3635, an additional substrate 4010 is affixed to the one or more electrodes 4020. For example, the one or more electrodes 4020 are the one or more electrodes 3540, the one or more electrodes 3870, and/or the one or more electrodes 3970. In another example, the process 3635 for affixing the additional substrate 4010 to the one or more electrodes 4020 includes at least one process selected from a group consisting of soldering with flux, flux-less soldering, brazing, silver painting, metal diffusion bonding, thermo-compression bonding, and the like. In yet another example, a solder used in the soldering with flux and/or the flux-less soldering includes at least one material from the group consisting of Ag, Cu, Sn, Pb, Au, In, Cd, Zn, Bi, and the like. In yet another example, the additional substrate 4010 includes at least one material from a group consisting of a semiconductor, a doped semiconductor, a semimetal, a metal, and a metal alloy, and the like. In yet another example the additional substrate includes Si and/or Cu. In yet another example, the Si is thermally matched to an array of nanostructures 4030. In yet another example, the Cu provides good electrical conductivity. In yet another example, the use of solder with the additional substrate 4010 including Si forms a strong mechanical bond needed in subsequent processing steps. In yet another example, the additional substrate 4010 is substantially flat. In yet another example, the additional substrate 4010 is configured to act as a handle for performing subsequent manufacturing processes.

Referring back to FIG. 6, at the process 3640 material is removed. For example, material from the substrate 4040 in which the array of nanostructures 4030 was formed, is removed. In another example, the substrate 4040 is substantially removed. In yet another example, the substrate 4040 is the substrate 3120.

In another example, the process 3640 for removing material includes coarse thinning. In yet another example, coarse thinning includes one or more processes selected from a group consisting of lapping, grinding, sanding, wet chemical etching, plasma etching, and spontaneous dry etching, and the like. In yet another example, spontaneous dry etching includes applying XeF₂ gas in a pressure controlled chamber. In yet another example, the coarse thinning removes a majority of the substrate 4040. In yet another example, the coarse thinning removes substantially all of the substrate 4040. In yet another example, the coarse thinning leaves behind less than 150 μm of the substrate 4040. In yet another example, the coarse thinning process is controlled based on the process 3635 used to affix the additional substrate 4010. In yet another example, the coarse thinning process is controlled so as not to damage a bond between the additional substrate 4010 and the one or more electrodes 4020. In yet another example, grinding is preferred when the additional substrate 4010 is affixed using silver paint. In yet another example, lapping is used when the additional substrate 4010 is affixed using solder. In yet another example, the array of nanostructures 4030 is too fragile to be directly exposed to the coarse thinning process.

In some embodiment, the process 3640 for removing material includes fine thinning. For example, fine thinning includes one or more processes selected from a group consisting of plasma etching, wet chemical etching, lapping, mechanical polishing, chemical mechanical polishing, and spontaneous dry etching, and the like. In another example, spontaneous dry etching includes applying XeF₂ gas in a pressure controlled chamber. In yet another example, plasma etching includes applying SF₆ in a vacuμm chamber. In yet another example, plasma etching includes applying SF₆ in a reactive ion etcher. In yet another example, the plasma etching is applied for a predetermined time period. In yet another example, the fine thinning process removes substantially all of the remaining portions of the substrate 4040. In yet another example, the fine thinning process removes up to 150 μm of the substrate 4040. In yet another example, the fine thinning process exposes at least some portion of the underlying array of nanostructures 4030. In yet another example, the fine thinning process removes a portion of the underlying array of nanostructures 4030.

FIG. 12B is a simplified diagram of the array of nanostructures 4030 with the substrate 4040 removed as formed by the process 3640 for removing material as part of the method 3600 for forming an array of nanostructures with protruding segments, contacts, and electrodes according to one embodiment of the present invention. This diagram is merely an example, which should not unduly limit the scope of the claims. One of ordinary skill in the art would recognize many variations, alternatives, and modifications. In FIG. 12B, the substrate 4040 has been removed using the process 3640 for removing material.

According to some embodiments, at the process 3645, exposed segments 4050 for each of the nanostructures in the array of nanostructures 4030 are formed. In another example, the exposed segments 4050 are the protruding segments 3145 as shown in FIG. 1. In yet another example, the process 3645 for exposing the exposed segments of the nanostructures includes removing a portion of the one or more fill materials. In yet another example, the process 3645 for exposing the exposed segments of the nanostructures includes etching using a HF solution. In yet another example, the HF solution includes at least one selected from a group consisting of a buffering agent, a surfactant, and other additives. In yet another example, the process 3645 for exposing the exposed segments of the nanostructures includes etching in a reactive ion etcher.

As discussed above and further emphasized here, FIGS. 12A and 12B are merely examples, which should not unduly limit the scope of the claims. One of ordinary skill in the art would recognize many variations, alternatives, and modifications. In some embodiments, the process 3640 for removing material and the process 3645 for exposing segments of the nanostructures uses a lapping jig.

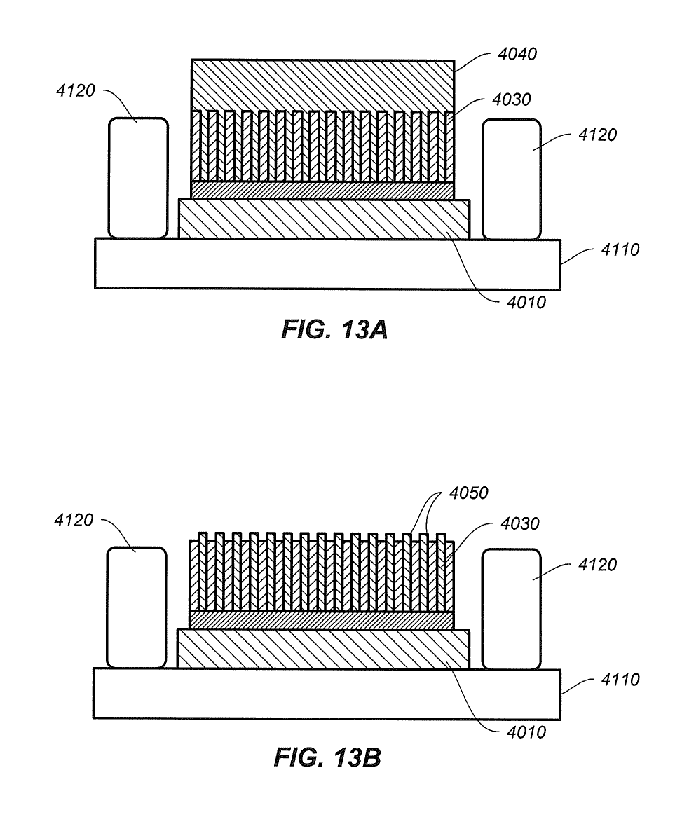

FIG. 13A is a simplified diagram of an array of nanostructures affixed to an additional substrate mounted in a lapping jig before the process 3640 for removing material as part of the method 3600 for forming an array of nanostructures with protruding segments, contacts, and electrodes according to one embodiment of the present invention. This diagram is merely an example, which should not unduly limit the scope of the claims. One of ordinary skill in the art would recognize many variations, alternatives, and modifications. In FIG. 13A, the additional substrate 4010 is mounted in a lapping part holder 4110. In one example, the array of nanostructures 4030 is mounted in the lapping part holder 4110 between one or more lapping stops 4120. In another example, the lapping stops 4120 include at steel and/or ceramic. In yet another example, the lapping stops 4120 have a predetermined height. In yet another example, the predetermined height is set to control the amount of the substrate 4040 removed during the process 3640. In yet another example, the predetermined height is set based on desired length of the array of nanostructures 4030. In yet another example, the lapping stops 4120 protect the array of nanostructures 4030 during lapping.

FIG. 13B is a simplified diagram of an array of nanostructures affixed to an additional substrate mounted in a lapping jig after the process 3644 for exposing the exposed segments of the nanostructure as part of the method 3600 for forming an array of nanostructures with protruding segments, contacts, and electrodes according to one embodiment of the present invention. This diagram is merely an example, which should not unduly limit the scope of the claims. One of ordinary skill in the art would recognize many variations, alternatives, and modifications. In FIG. 13B, segments 4050 of the array of nanostructures 4030 are exposed. In one example, the segments 4050 are the protruding segments 3155 as shown in FIG. 1.

FIG. 12C is a simplified diagram of the array of nanostructures 4030 with one or more contacts on the exposed segments 4050 of the array nanostructures 4030 as formed by the process 3650 for forming one or more contacts as part of the method 3600 for forming an array of nanostructures with protruding segments, contacts, and electrodes according to one embodiment of the present invention. This diagram is merely an example, which should not unduly limit the scope of the claims. One of ordinary skill in the art would recognize many variations, alternatives, and modifications. For example, at the optional process 3650, the exposed segments 4050 of the array of nanostructures 4030 have one or more contacts 4060 formed thereon. In another example, the one or more contacts 4060 are the one or more contacts 3420 as shown in FIG. 4. In yet another example, the process 3650 for forming the contacts includes at least one process selected from a group consisting of electrolytic plating, electroless plating, evaporation, sputtering, molecular beam epitaxy, chemical vapor deposition, atomic layer deposition, and the like.

In yet another example, the one or more contacts 4060 each include one or more conductive materials. For example, the one or more conductive materials include at least one selected from a group consisting of semiconductors, semi-metals, metals, and the like. In another example, the semiconductors are each selected from a group consisting of Si, Ge, C, B, P, N, Ga, As, In, and the like. In yet another example, the semiconductors are doped. In yet another example, the semi-metals are selected from a group consisting of B, Ge, Si, Sn, W, Ti, Mg, and the like. In yet another example, the metals are selected from a group consisting of Ti, Al, Cu, Au, Ag, Pt, Ni, P, B, Cr, Li, W, Mg, TiW, TiNi, TiN, Mo, TiSi, MoSi, WSi, and the like. In yet another example, the one or more contacts 4060 include TiW in a 10 to 90 ratio. In yet another example, the one or more contacts 4060 include TiW in a 10 to 90 ratio and Ni. In yet another example, a TiW layer is about 5000 Å thick. In yet another example, a Ni layer is about 5000 Å thick.

In yet another example, the one or more contacts 4060 form one or more electric contacts with the segments 3850. In yet another example, the one or more contacts 3860 form one or more ohmic contacts with the exposed segments 4050. In yet another example, the one or more contacts 4060 are configured to form one or more good thermal contacts with one or more surfaces for establishing one or more thermal paths through the array of nanostructures 4030 while limiting thermal leakage in one or more fill materials.

As discussed above and further emphasized here, FIG. 12C is merely an example, which should not unduly limit the scope of the claims. One of ordinary skill in the art would recognize many variations, alternatives, and modifications. In some embodiments, different styles of contacts are formed on the exposed segments 4050 of the array of nanostructures 4030. For example, each of the exposed segments 4050 is covered by a respective one of the one or more contacts as shown in FIG. 2. In another example, the one or more contacts form a conformal coating on the exposed segments 4050 and the one or more fill materials as shown in FIG. 3. In some embodiments, different areas of the array of nanostructures 4030 are covered by different contacts that are not contiguous with each other. For example, a plurality of the exposed segments 4050 are covered by a contact selected from the one or more contacts 4060. In another example, another plurality of the exposed segments 4050 are covered by another contact selected from the one or more contacts 4060. In yet another example, the contact and the another contact are not contiguous with each other and they are formed by the same or different materials.

FIG. 12D is a simplified diagram of the array of nanostructures 4030 with one or more electrodes on the one or more contacts 4060 as formed by the metalization process 3655 as part of the method 3600 for forming an array of nanostructures with protruding segments, contacts, and electrodes according to one embodiment of the present invention. This diagram is merely an example, which should not unduly limit the scope of the claims. One of ordinary skill in the art would recognize many variations, alternatives, and modifications. According to some embodiments, at the process 3655, metalization is used to form one or more electrodes 4070 on the one or more contacts 4060. For example, the one or more electrodes 4070 are the one or more electrodes 3550. In another example, the metalization process 3630 includes at least one process selected from a group consisting of electrolytic plating, electroless plating, evaporation, sputtering, molecular beam epitaxy, chemical vapor deposition, atomic layer deposition, and the like. In yet another example, the chemical vapor deposition occurs at low pressure. In yet another example, the chemical vapor deposition is plasma enhanced. In yet another example, the one or more electrodes 3870 each include one or more conductive materials. For example, the one or more conductive materials include at least one selected from a group consisting of Ti, Al, Cu, Au, Ag, Pt, Ni, P, B, Cr, Li, W, Mg, TiW, TiNi, TiN, Mo, TiSi, MoSi, NiSi, WSi, and the like. In yet another example, the one or more electrodes 4070 include TiW in a 10 to 90 ratio. In yet another example, the one or more electrodes 4070 include TiW in a 10 to 90 ratio and Ni. In yet another example, a TiW layer is about 5000 Å thick. In yet another example, a Ni layer is about 5000 Å thick.

As discussed above and further emphasized here, FIG. 12D is merely an example, which should not unduly limit the scope of the claims. One of ordinary skill in the art would recognize many variations, alternatives, and modifications. In some embodiments, the one or more electrodes are formed in place of the one or more contacts. For example, the one or more electrodes are formed directly on the one or more fill materials and/or the exposed segments 4050 of the array of nanostructures 4030.

As discussed above and further emphasized here, FIGS. 6-12 are merely examples, which should not unduly limit the scope of the claims. One of ordinary skill in the art would recognize many variations, alternatives, and modifications. In some embodiments, the additional substrate 4010 provides a thermally and/or electrically conductive contact of a thermoelectric device. In certain embodiments, the flat additional substrate 4010 provides good thermal conduction to the array of nanostructures 4030. In some embodiments, the additional substrate 4010 is removed after process 3600 completes.

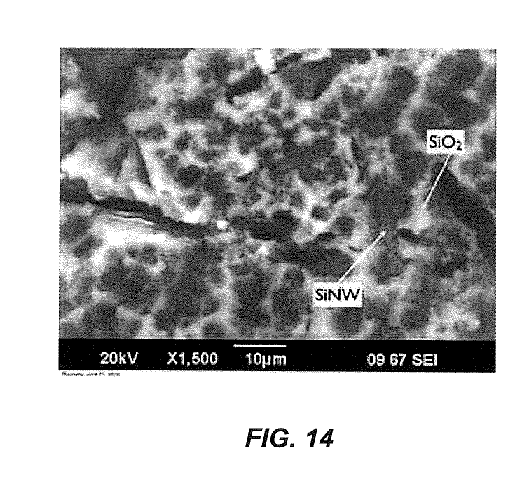

FIG. 14 is a scanning electron microscope image showing a surface of an array of nanostructures before exposure of the exposed segments of the array of nanostructures as part of the method 3600 for forming an array of nanostructures with protruding segments, contacts, and electrodes according to one embodiment of the present invention. These image is merely an example, which should not unduly limit the scope of the claims. One of ordinary skill in the art would recognize many variations, alternatives, and modifications. As shown in FIG. 14 the exposed segments of the array of nanostructures are not well exposed. For example, the plurality of darker regions in FIG. 14 represent the nanostructures. In another example, the plurality of lighter regions in FIG. 14 represent the one or more fill materials. In yet another example, the presence of the one or more fill materials make the formation of high quality electrical and/or thermal contacts difficult. In yet another example, FIG. 14 depicts the array of nanostructures 3820 or the array of nanostructures 3920 prior to the process 3620 for exposing segments of the nanostructures. In yet another example, FIG. 14 depicts the array of nanostructures 4030 prior to the process 3645 for exposing segments of the nanostructures.

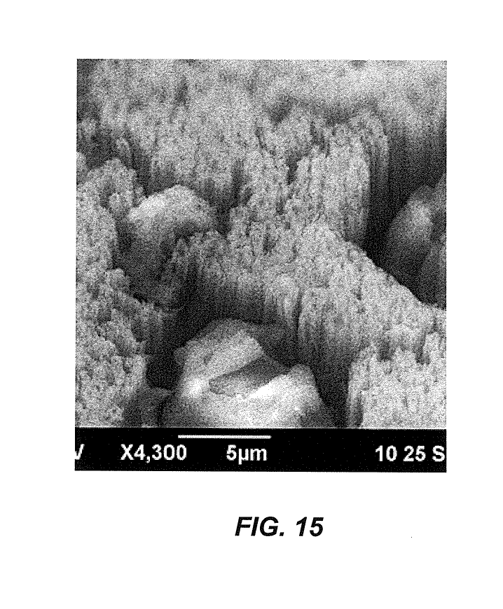

FIG. 15 is a scanning electron microscope image showing a surface of an array of nanostructures after exposure of the exposed segments of the array of nanostructures as part of the method 3600 for forming an array of nanostructures with protruding segments, contacts, and electrodes according to one embodiment of the present invention. These image is merely an example, which should not unduly limit the scope of the claims. One of ordinary skill in the art would recognize many variations, alternatives, and modifications. As shown in FIG. 15 the exposed segments of the array of nanostructures are well exposed. For example, the exposed segments of the array of nanostructures are effectively protruding. In another example, FIG. 15 depicts the array of nanostructures 3820 or the array of nanostructures 3920 after the process 3620 for exposing segments of the nanostructures. In yet another example, FIG. 15 depicts the array of nanostructures 4030 after the process 3645 for exposing segments of the nanostructures.

According to one embodiment, a structure for at least one array of nanowires partially embedded in a matrix includes nanowires and one or more fill materials located between the nanowires. Each of the nanowires including a first segment associated with a first end, a second segment associated with a second end, and a third segment between the first segment and the second segment. The nanowires are substantially parallel to each other and are fixed in position relative to each other by the one or more fill materials. The third segment is substantially surrounded by the one or more fill materials. The first segment protrudes from the one or more fill materials. For example, the structure is implemented according to at least FIG. 1.

In another example, the structure further includes one or more first contacts associated with at least the first segment. In yet another example, the one or more first contacts conformally coat at least the first end. In yet another example, the one or more first contacts are not contiguous with each other. In yet another example, the or more first contacts conformally coat at least the first segment and at least one surface of the one or more fill materials. In yet another example, the one or more first contacts substantially fill at least the space between the first segment of a first nanowire selected from the nanowires and the first segment of a second nanowire selected from the nanowires. In yet another example, the structure further includes one or more first electrodes formed on the one or more first contacts. In yet another example, the second segment is substantially surrounded by the one or more fill materials.

In yet another example, the one or more contacts include at least one or more materials selected form a group consisting of a semiconductor, a semi-metal, and a metal. In yet another example, the semiconductor includes at least one selected from a group consisting of Si, Ge, C, B, P, N, Ga, As, and In. In yet another example, the semi-metal includes at least one selected from a group consisting of B, Ge, Si, and Sn. In yet another example, the metal includes at least one selected from a group consisting of Ti, Al, Cu, Au, Ag, Pt, Ni, P, B, Cr, Li, W, Mg, TiW, TiNi, TiN, Mo, TiSi, MoSi, and WSi. In yet another example, the one or more first electrodes include at least one or more materials selected form a group consisting of Ti, Al, Cu, Au, Ag, Pt, Ni, P, B, Cr, Li, W, Mg, TiW, TiNi, TiN, Mo, TiSi, MoSi, NiSi, and WSi. In yet another example, the one or more fill materials each include at least one material selected from a group consisting of photoresist, spin-on glass, spin-on dopant, aerogel, xerogel, nitride, and oxide.

In yet another example, the second segment protrudes from the one or more fill materials. In yet another example, the structure further includes one or more second contacts associated with at least the second segment. In yet another example, the one or more second contacts conformally coat at least the second end. In yet another example, the one or more second contacts are not contiguous with each other. In yet another example, the one or more second contacts conformally coat at least the second segment and at least one surface of the one or more fill materials. In yet another example, the one or more second contacts substantially fill at least the space between the second segment of a first nanowire selected from the nanowires and the second segment of a second nanowire selected from the nanowires.

In yet another example, the structure further includes one or more second electrodes formed on the one or more second contacts. In yet another example, the structure further includes one or more first contacts associated with at least the first segment and one or more first electrodes formed on the one or more first contacts. In yet another example, the structure is a part of a thermoelectric device.

In yet another example, a distance between the first end and the second end is at least 300 μm. In yet another example, the distance is at least 525 μm. In yet another example, the nanowires correspond to an area, the area being approximately 0.0001 mm2 in size. In yet another example, the nanowires correspond to an area, the area being smaller than 0.01 mm2 in size. In yet another example, the nanowires correspond to an area, the area being at least 100 mm2 in size. In yet another example, the area is at least 5000 mm2 in size. In yet another example, each of the one or more fill materials is associated with a thermal conductivity less than 50 Watts per meter per degree Kelvin. In yet another example, the thermal conductivity is less than 1 Watts per meter per degree Kelvin. In yet another example, the structure is associated with at least a sublimation temperature or a melting temperature, the sublimation temperature or the melting temperature being above 350° C. In yet another example, the melting temperature or the sublimation temperature is above 800° C.

According to another embodiment, a structure for at least one array of nanostructures partially embedded in a matrix includes nanostructures and one or more fill materials. Each of the nanostructures including a first segment associated with a first end, a second segment associated with a second end, and a third segment between the first segment and the second segment, the nanostructures corresponding to voids. The one or more fill materials are located at least within the voids. Each of the nanostructures includes a semiconductor material. The nanostructures are substantially parallel to each other and are fixed in position relative to each other by the one or more fill materials. The voids corresponding to the third segment are substantially filled by the one or more fill materials. The first segment protrudes from the one or more fill materials. For example, the structure is implemented according to at least FIG. 1.

In another example, the second segment protrudes from the one or more fill materials. In yet another example, the nanostructures correspond to nanoholes and the nanoholes are the voids. In yet another example, the nanostructures correspond to nanowires and spaces surrounding the nanowires are the voids.

According to yet another embodiment, a thermoelectric device, the device includes nanostructures, each of the nanostructures including a first segment associated with a first end, a second segment associated with a second end, and a third segment between the first segment and the second segment, the nanostructures corresponding to voids; one or more fill materials located at least within the voids; one or more first electrodes associated with the first segment; and one or more second electrodes associated with the second segment. Each of the nanostructures includes a semiconductor material. The nanostructures are substantially parallel to each other and are fixed in position relative to each other by the one or more fill materials. The voids corresponding to the third segment are substantially filled by the one or more fill materials. The first segment protrudes from the one or more fill materials. The second segment protrudes from the one or more fill materials. For example, the thermoelectric device is implemented according to at least FIG. 5 and/or FIG. 12D.

In another example, the thermoelectric device further includes one or more first contacts associated with at least the first segment and one or more second contacts associated with at least the second segment. The one or more first electrodes are formed on the one or more first contacts. The one or more second electrodes are formed on the one or more second contacts.

According to yet another embodiment, a method for making a thermoelectric device includes forming nanostructures in a substrate, the nanostructures including a semiconductor material, a first segment associated with a first end, a second segment associated with a second end, and a third segment between the first segment and the second segment; filling voids corresponding to the nanostructures with at least one or more fill materials; exposing at least the first segment; forming one or more first electrodes associated with the first segment; removing at least a portion of the substrate; exposing at least the second segment; and forming one or more second electrodes associated with the second segment. The process for filling the voids includes keeping the nanostructures substantially parallel to each other, fixing the nanostructures in position relative to each other by the one or more fill materials, and substantially filling the voids corresponding to the third segment with the one or more fill materials. For example, the method is implemented according to at least FIG. 6.

In another example, the method further includes planarizing the nanostructures. In yet another example, the process for exposing at least the first segment includes etching using a HF solution. In yet another example, the HF solution includes at least one selected from a group consisting of a buffering agent and a surfactant. In yet another example, the process for exposing at least the first segment includes etching in a reactive ion etcher. In yet another example, the method further includes forming one or more contacts on at least the first segment. The process for forming one or more first electrodes includes forming the one or more first electrodes on at least the one or more contacts. In yet another example, the method further includes affixing an additional substrate to the one or more first electrodes. In yet another example, the additional substrate includes at least one or more materials selected form a group consisting of Si and Cu. In yet another example, the method further includes forming one or more contacts on at least the second segment. The process for forming one or more second electrodes includes forming the one or more second electrodes on at least the one or more contacts.

In yet another example, the process for removing at least a portion of the substrate includes coarse thinning. In yet another example, the process for coarse thinning includes at least one process selected from a group consisting of lapping, grinding, sanding, wet chemical etching, plasma etching, and spontaneous dry etching. In yet another example, the process for removing at least a portion of the substrate includes fine thinning. In yet another example, the process for fine thinning includes at least one process selected from a group consisting of plasma etching, wet chemical etching, lapping, mechanical polishing, chemical mechanical polishing, and spontaneous dry etching. In yet another example, the process for removing at least a portion of the substrate includes using a lapping jig including at least one lapping stop.

Although specific embodiments of the present invention have been described, it will be understood by those of skill in the art that there are other embodiments that are equivalent to the described embodiments. For example, various embodiments and/or examples of the present invention can be combined. Accordingly, it is to be understood that the invention is not to be limited by the specific illustrated embodiments, but only by the scope of the appended claims.

What is claimed is:

1. A structure for at least one array of nanowires partially embedded in a matrix, the structure comprising:
nanowires, each of the nanowires including a first segment associated with a first end, a second segment associated with a second end, and a third segment between the first segment and the second segment; and
one or more fill materials located between the nanowires;
wherein:
the nanowires are substantially parallel to each other and are fixed in position relative to each other by the one or more fill materials;
the third segment is substantially surrounded by the one or more fill materials; and
the first segment protrudes from the one or more fill materials.

2. The structure of claim 1, and further comprising one or more first contacts associated with at least the first segment.

3. The structure of claim 2 wherein the one or more first contacts conformally coat at least the first end.

4. The structure of claim 3 wherein the one or more first contacts are not contiguous with each other.

5. The structure of claim 2 wherein the one or more first contacts conformally coat at least the first segment and at least one surface of the one or more fill materials.

6. The structure of claim 2 wherein the one or more first contacts substantially fill at least the space between the first segment of a first nanowire selected from the nanowires and the first segment of a second nanowire selected from the nanowires.

7. The structure of claim 2, and further comprising one or more first electrodes formed on the one or more first contacts.

8. The structure of claim 1 wherein the second segment is substantially surrounded by the one or more fill materials.

9. The structure of claim 2 wherein the one or more contacts include at least one or more materials selected form a group consisting of a semiconductor, a semi-metal, and a metal.

10. The structure of claim 9 wherein the semiconductor includes at least one selected from a group consisting of Si, Ge, C, B, P, N, Ga, As, and In.

11. The structure of claim 9 wherein the semi-metal includes at least one selected from a group consisting of B, Ge, Si, and Sn.

12. The structure of claim 9 wherein the metal includes at least one selected from a group consisting of Ti, Al, Cu, Au, Ag, Pt, Ni, P, B, Cr, Li, W, Mg, TiW, TiNi, TiN, Mo, TiSi, MoSi, and WSi.

13. The structure of claim 7 wherein the one or more first electrodes include at least one or more materials selected form a group consisting of Ti, Al, Cu, Au, Ag, Pt, Ni, P, B, Cr, Li, W, Mg, TiW, TiNi, TiN, Mo, TiSi, MoSi, NiSi, and WSi.

14. The structure of claim 1 wherein the one or more fill materials each include at least one material selected from a group consisting of photoresist, spin-on glass, spin-on dopant, aerogel, xerogel, nitride, and oxide.

15. The structure of claim 1 wherein the second segment protrudes from the one or more fill materials.

16. The structure of claim 15, and further comprising one or more second contacts associated with at least the second segment.

17. The structure of claim 16 wherein the one or more second contacts conformally coat at least the second end.

18. The structure of claim 17 wherein the one or more second contacts are not contiguous with each other.

19. The structure of claim 16 wherein the one or more second contacts conformally coat at least the second segment and at least one surface of the one or more fill materials.

20. The structure of claim 16 wherein the one or more second contacts substantially fill at least the space between the second segment of a first nanowire selected from the nanowires and the second segment of a second nanowire selected from the nanowires.

21. The structure of claim 16, and further comprising one or more second electrodes formed on the one or more second contacts.

22. The structure of claim 21, and further comprising:
one or more first contacts associated with at least the first segment; and
one or more first electrodes formed on the one or more first contacts.

23. The structure of claim 1 wherein the structure is a part of a thermoelectric device.

24. The structure of claim 1 wherein a distance between the first end and the second end is at least 300 μm.

25. The structure of claim 24 wherein the distance is at least 525 μm.

26. The structure of claim 1 wherein the nanowires correspond to an area, the area being approximately 0.0001 mm² in size.

27. The structure of claim 1 wherein the nanowires correspond to an area, the area being smaller than 0.01 mm² in size.

28. The structure of claim 1 wherein the nanowires correspond to an area, the area being at least 100 mm² in size.

29. The structure of claim 28 wherein the area is at least 5000 mm² in size.

30. The structure of claim 1 wherein each of the one or more fill materials is associated with a thermal conductivity less than 50 Watts per meter per degree Kelvin.

31. The structure of claim 30 wherein the thermal conductivity is less than 1 Watts per meter per degree Kelvin.

32. The structure of claim 1 wherein the structure is associated with at least a sublimation temperature or a melting temperature, the sublimation temperature or the melting temperature being above 350° C.

33. The structure of claim 32 wherein the melting temperature or the sublimation temperature is above 800° C.

34. A structure for at least one array of nanostructures partially embedded in a matrix, the structure comprising:
nanostructures, each of the nanostructures including a first segment associated with a first end, a second segment associated with a second end, and a third segment between the first segment and the second segment, the nanostructures corresponding to voids; and
one or more fill materials located at least within the voids;
wherein:
each of the nanostructures includes a semiconductor material;
the nanostructures are substantially parallel to each other and are fixed in position relative to each other by the one or more fill materials;
the voids corresponding to the third segment are substantially filled by the one or more fill materials; and
the first segment protrudes from the one or more fill materials.

35. The structure of claim 34 wherein the second segment protrudes from the one or more fill materials.

36. The structure of claim 34 wherein:
the nanostructures correspond to nanoholes; and
the nanoholes are the voids.

37. The structure of claim 34 wherein:
the nanostructures correspond to nanowires; and
spaces surrounding the nanowires are the voids.

38. A thermoelectric device, the device comprising:
nanostructures, each of the nanostructures including a first segment associated with a first end, a second segment associated with a second end, and a third segment between the first segment and the second segment, the nanostructures corresponding to voids;
one or more fill materials located at least within the voids;
one or more first electrodes associated with the first segment; and
one or more second electrodes associated with the second segment;
wherein:
each of the nanostructures includes a semiconductor material;
the nanostructures are substantially parallel to each other and are fixed in position relative to each other by the one or more fill materials;
the voids corresponding to the third segment are substantially filled by the one or more fill materials;
the first segment protrudes from the one or more fill materials; and
the second segment protrudes from the one or more fill materials.

39. The device of claim 38, and further comprising:
one or more first contacts associated with at least the first segment; and
one or more second contacts associated with at least the second segment;
wherein:
the one or more first electrodes are formed on the one or more first contacts; and
the one or more second electrodes are formed on the one or more second contacts.

40. A method for making a thermoelectric device, the method comprising:
forming nanostructures in a substrate, the nanostructures including a semiconductor material, a first segment associated with a first end, a second segment associated with a second end, and a third segment between the first segment and the second segment;
filling voids corresponding to the nanostructures with at least one or more fill materials;
exposing at least the first segment;
forming one or more first electrodes associated with the first segment;
removing at least a portion of the substrate;
exposing at least the second segment; and
forming one or more second electrodes associated with the second segment;
wherein the process for filling the voids includes:
keeping the nanostructures substantially parallel to each other;
fixing the nanostructures in position relative to each other by the one or more fill materials; and
substantially filling the voids corresponding to the third segment with the one or more fill materials.

41. The method of claim 40, and further comprising planarizing the nanostructures.

42. The method of claim 40, wherein the process for exposing at least the first segment includes etching using a HF solution.

43. The method of claim 42, wherein the HF solution includes at least one selected from a group consisting of a buffering agent and a surfactant.

44. The method of claim 40, wherein the process for exposing at least the first segment includes etching in a reactive ion etcher.

45. The method of claim 40, and further comprising:
forming one or more contacts on at least the first segment;
wherein the process for forming one or more first electrodes includes forming the one or more first electrodes on at least the one or more contacts.

46. The method of claim 40, and further comprising affixing an additional substrate to the one or more first electrodes.

47. The method of claim 46 wherein the additional substrate includes at least one or more materials selected form a group consisting of Si and Cu.

48. The method of claim 40, and further comprising:
forming one or more contacts on at least the second segment;
wherein the process for forming one or more second electrodes includes forming the one or more second electrodes on at least the one or more contacts.

49. The method of claim 40, wherein the process for removing at least a portion of the substrate includes coarse thinning.

50. The method of claim 49, wherein the process for coarse thinning includes at least one process selected from a group consisting of lapping, grinding, sanding, wet chemical etching, plasma etching, and spontaneous dry etching.

51. The method of claim 40, wherein the process for removing at least a portion of the substrate includes fine thinning.

52. The method of claim 51, wherein the process for fine thinning includes at least one process selected from a group consisting of plasma etching, wet chemical etching, lapping, mechanical polishing, chemical mechanical polishing, and spontaneous dry etching.

53. The method of claim 40, wherein the process for removing at least a portion of the substrate includes using a lapping jig including at least one lapping stop.
